(19) United States
(12) Patent Application Publication
(10) Pub. No.: US 2026/0059916 A1
(43) Pub. Date: Feb. 26, 2026

(54) Light-Emitting Substrate, Backlight Module, Display Module and Display Apparatus

(71) Applicants: Hefei BOE Ruisheng Technology Co., Ltd., Hefei, Anhui (CN); BOE TECHNOLOGY GROUP CO., LTD., Chaoyang District, Beijing (CN)

(72) Inventors: Bing Zhang, Beijing (CN); Xiao Wang, Beijing (CN); Xing Liu, Beijing (CN); Kangli Wang, Beijing (CN); Liang Gao, Beijing (CN)

(21) Appl. No.: 18/874,730

(22) PCT Filed: Sep. 11, 2023
(86) PCT No.: PCT/CN2023/118021

§ 371 Date: Dec. 13, 2024

(30) Foreign Application Priority Data
Nov. 15, 2022 (CN) 202211437806.8

(51) Int. Cl. H10H 29/49

(52) U.S. Cl. CPC H10H 29/49

(57) ABSTRACT

A light-emitting substrate includes a substrate, a plurality of signal lines, one or more support structures and a device layer. The substrate includes a first surface. The plurality of signal lines are disposed on the first surface. The one or more support structures are disposed on the first surface. The device layer is disposed on a side of the plurality of signal lines away from the first surface. A ratio of an overlapping area of an orthographic projection of any signal line of the plurality of signal lines on the substrate and an orthographic projection of at least one support structure of the one or more support structures on the substrate to an area of the orthographic projection of the at least one support structure on the substrate is greater than or equal to zero and less than or equal to 0.1.

### CROSS-REFERENCE TO RELATED APPLICATIONS

This application is the United States National Phase of International Patent Application No. PCT/CN2023/118021, filed Sep. 11, 2023, and claims priority to Chinese Patent Application No. 202211437806.8, filed Nov. 15, 2022, the disclosures of which are hereby incorporated by reference in their entireties.

### BACKGROUND OF THE INVENTION

### Field of the Invention

The present disclosure relates to the field of display technologies, and in particular, to a light-emitting substrate, a backlight module, a display module and a display apparatus.

### Description of Related Art

A backlight module includes a light-emitting substrate and an optical film group, and support pillars are provided between the light-emitting substrate and the optical film group for supporting the optical film group, so that there is a certain distance between the light-emitting substrate and the optical film group. For an aluminum substrate or a printed circuit board (PCB) substrate, the support pillars may be riveted into positioning holes in the substrate; however, for a glass substrate, forming holes in its surface will reduce the strength of the glass substrate. Therefore, the support pillars are generally glued to the glass substrate with a hot melt adhesive.

In a case where a support pillar is displaced by force, the hot melt adhesive at the bottom of the support pillar will also be displaced accordingly. If the hot melt adhesive is displaced to be in contact with a signal trace on the light-emitting substrate, the signal trace will be subjected to the force applied by the hot melt adhesive, so that the signal trace may be at risk of being peeled off from the light-emitting substrate.

### SUMMARY OF THE INVENTION

In an aspect, a light-emitting substrate is provided. The light-emitting substrate includes a substrate, a plurality of signal lines, one or more support structures and a device layer. The substrate includes a first surface. The plurality of signal lines are disposed on the first surface. The one or more support structures are disposed on the first surface. The device layer is disposed on a side of the plurality of signal lines away from the first surface. A ratio of an overlapping area of an orthographic projection of any signal line of the plurality of signal lines on the substrate and an orthographic projection of at least one support structure of the one or more support structures on the substrate to an area of the orthographic projection of the at least one support structure on the substrate is greater than or equal to zero and less than or equal to 0.1.

In some embodiments, the plurality of signal lines include at least one first signal line, a first signal line of the at least one first signal line includes at least two straight sub-portions and at least one detour sub-portion, and all straight sub-portions and all detour sub-portions of the first signal line are alternately arranged. A straight sub-portion of the first signal line extends in the first direction and includes an inner border and an outer border both extending in the first direction, and an orthographic projection of an extension line of the inner border of the straight sub-portion of the first signal line on the substrate passes through the orthographic projection of the support structure adjacent to the straight sub-portion on the substrate.

An orthographic projection of a support structure of the one or more support structures on the substrate is divided into a first sub-region and a second sub-region by a reference line extending in a first direction, and a maximum value of a dimension of the first sub-region in a second direction is equal to a maximum value of a dimension of the second sub-region in the second direction. The first direction is perpendicular to the second direction.

A detour sub-portion of the first signal line includes an inner border proximate to the reference line and an outer border away from the reference line, the inner border of the detour sub-portion of the first signal line is connected to the inner border of the straight sub-portion of the first signal line, and the outer border of the detour sub-portion of the first signal line is connected to the outer border of the straight sub-portion of the first signal line.

In the second direction, a maximum value of a distance between the reference line and the inner border of the detour sub-portion of the first signal line is greater than a distance between the reference line and the inner border of the straight sub-portion of the first signal line. The outer border of the detour sub-portion of the first signal line is located on a side of the support structure in the second direction, an orthographic projection of the outer border of the detour sub-portion of the first signal line on the substrate is non-overlapping with the orthographic projection of the support structure on the substrate, and a distance between the reference line and the outer border of the detour sub-portion of the first signal line is greater than a distance between the reference line and the outer border of the straight sub-portion of the first signal line.

In some embodiments, the detour sub-portion of the first signal line is located on a side of the support structure. A symmetry axis, extending in the first direction, of the straight sub-portion of the first signal line is located on a side of the reference line. The detour sub-portion of the first signal line and the symmetry axis are located on a same side of the reference line.

In some other embodiments, the detour sub-portion of the first signal line is located on a side of the support structure. The symmetry axis, extending in the first direction, of the straight sub-portion of the first signal line coincides with the reference line, and the detour sub-portion of the first signal line is located on either side of the reference line.

In some embodiments, a dimension of the detour sub-portion of the first signal line in a direction perpendicular to an extension direction of the detour sub-portion of the first signal line is greater than or equal to a dimension of the straight sub-portion of the first signal line in a direction perpendicular to an extension direction of the straight sub-portion of the first signal line.

In some embodiments, the plurality of signal lines include at least one second signal line, and a second signal line of the at least one second signal line is adjacent to at least one first signal line. The second signal line includes at least two straight sub-portions and at least one detour sub-portion, and all straight sub-portions and all detour sub-portions of the second signal line are alternately arranged. A straight sub-portion of the second signal line extends in the first direction, and a detour sub-portion of the second signal line is further away from the support structure than the detour sub-portion of the first signal line.

In some embodiments, the detour sub-portion of the second signal line is arranged along a border of the detour sub-portion of the first signal line adjacent to the second signal line. The straight sub-portion of the second signal line includes an inner border and an outer border both extending in the first direction.

The detour sub-portion of the second signal line includes an inner border proximate to the first signal line adjacent to the second signal line and an outer border away from the first signal line adjacent to the second signal line. The inner border of the detour sub-portion of the second signal line is connected to the inner border of the straight sub-portion of the second signal line, and the outer border of the detour sub-portion of the second signal line is connected to the outer border of the straight sub-portion of the second signal line. A shape of the inner border of the detour sub-portion of the second signal line is same as a shape of the outer border of the detour sub-portion of the first signal line adjacent to the second signal line.

In some embodiments, a dimension of the detour sub-portion of the second signal line in a direction perpendicular to an extension direction of the detour sub-portion of the second signal line is greater than or equal to a dimension of the straight sub-portion of the second signal line in a direction perpendicular to an extension direction of the straight sub-portion of the second signal line.

In some embodiments, the plurality of signal lines include at least one first signal line, a first signal line of the at least one first signal line includes at least two straight sub-portions and at least one detour sub-portion, and all straight sub-portions and all detour sub-portions of the first signal line are alternately arranged.

A straight sub-portion of the first signal line extends in a first direction and includes an inner border and an outer border both extending in the first direction, and an orthographic projection of an extension line of the inner border of the straight sub-portion of the first signal line on the substrate passes through an orthographic projection of a support structure adjacent to the straight sub-portion on the substrate. The orthographic projection of the support structure on the substrate is divided into a first sub-region and a second sub-region by a reference line extending in the first direction, and a maximum value of a dimension of the first sub-region in a second direction is equal to a maximum value of a dimension of the second sub-region in the second direction. The first direction is perpendicular to the second direction.

A detour sub-portion of the first signal line includes an inner border proximate to the reference line and an outer border away from the reference line, the inner border of the detour sub-portion of the first signal line is connected to the inner border of the straight sub-portion of the first signal line, and the outer border of the detour sub-portion of the first signal line is connected to the outer border of the straight sub-portion of the first signal line.

A region covered by the orthographic projection of the support structure on the substrate is a support region. In the second direction, a maximum value of a distance between the reference line and the inner border of the detour sub-portion of the first signal line is greater than a distance between the reference line and the inner border of the straight sub-portion of the first signal line; the outer border of the detour sub-portion of the first signal line is located on a side of the support structure in the second direction, an orthographic projection of the outer border of the detour sub-portion of the first signal line on the substrate is non-overlapping with the orthographic projection of the support structure on the substrate, and the outer border of the detour sub-portion of the first signal line is collinear with the outer border of the straight sub-portion of the first signal line.

In some embodiments, a dimension of the detour sub-portion of the first signal line in a direction perpendicular to an extension direction of the detour sub-portion of the first signal line is less than a dimension of the straight sub-portion of the first signal line in a direction perpendicular to an extension direction of the straight sub-portion of the first signal line. The dimension of the detour sub-portion of the first signal line in the direction perpendicular to the extension direction of the detour sub-portion of the first signal line is greater than or equal to 100 μm.

In some embodiments, the detour sub-portion of the first signal line is arranged along a border of the orthographic projection of the support structure on the substrate, and a shape of the inner border of the detour sub-portion of the first signal line matches a shape of the border of the orthographic projection of the support structure on the substrate.

In some embodiments, the plurality of signal lines include at least two first signal lines, and the support structure is surrounded by detour sub-portions of two first signal lines of the at least two first signal lines adjacent to the support structure.

In some embodiments, the light-emitting substrate further includes an insulating layer disposed on a side of the plurality of signal lines away from the first surface, and the insulating layer covers the plurality of signal lines. The insulating layer is located between the plurality of signal lines and the support structure, and an orthographic projection of the insulating layer on the substrate overlaps with the orthographic projection of the support structure on the substrate. In a direction perpendicular to the first surface, a distance between the first surface and a surface of a portion of the insulating layer located between the support structure and the substrate is less than a distance between the first surface and a surface of a portion of the insulating layer covering the plurality of signal lines.

In some embodiments, a region covered by the orthographic projection of the support structure on the substrate is a support region. An adhesive is provided in the support region, and an end of the support structure is fixed to the support region by the adhesive.

In some other embodiments, the region covered by the orthographic projection of the support structure on the substrate is the support region. A blind hole is provided in the support region, and an end of the support structure is disposed in the blind hole.

In yet some other embodiments, the region covered by the orthographic projection of the support structure on the substrate is the support region. A through hole penetrating the substrate in the direction perpendicular to the first surface is provided in the support region, and an end of the support structure is disposed in the through hole.

In some embodiments, a colour of the support structure includes but is not limited to white.

In some embodiments, a shape the orthographic projection of the support structure on the substrate includes, but is not limited to, a circle, an ellipse or a polygon.

In some embodiments, the device layer includes a plurality of light-emitting devices and a plurality of driving circuits. The plurality of driving circuits are configured to drive the plurality of light-emitting devices to emit light.

In another aspect, a backlight module is provided. The backlight module includes: the light-emitting substrate according to any of the above embodiments and an optical film group. The optical film group is disposed on a side of the device layer away from the substrate. The device layer and the optical film group have a set distance therebetween.

An end of a support structure included in the light-emitting substrate away from the substrate abuts against the optical film group.

In yet another aspect, a display module is provided. The display module includes: the backlight module according to the above embodiment and a display panel. The display panel is disposed on a side of the optical film group away from the light-emitting substrate.

The display module has the same structure and beneficial effects as the light-emitting substrate of some of the above embodiments, which will not be repeated here.

In yet another aspect, a display apparatus is provided. The display apparatus includes the display module according to the above embodiment.

### BRIEF DESCRIPTION OF THE DRAWINGS

In order to describe the technical solutions in the present disclosure more clearly, the accompanying drawings to be used in some embodiments of the present disclosure will be briefly introduced below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1A is a sectional view of a backlight module, in accordance with some examples;

FIG. 1B is a sectional view obtained by taking along the section line AA in FIG. 1A;

FIG. 2 is a plan view of a light-emitting substrate, in accordance with some other embodiments;

FIG. 3A is an enlarged view of the region C of the light-emitting substrate in FIG. 2, in accordance with some embodiments;

FIG. 3B is another enlarged view of the region C of the light-emitting substrate in FIG. 2, in accordance with some other embodiments;

FIG. 4A is an enlarged view of the region D of the light-emitting substrate in FIG. 2, in accordance with some embodiments;

FIG. 4B is another enlarged view of the region D of the light-emitting substrate in FIG. 2, in accordance with some other embodiments;

FIG. 5 is a structural diagram of a second signal line in a light-emitting substrate, in accordance with some embodiments;

FIG. 6 is a structural diagram of a second signal line in a light-emitting substrate, in accordance with some other embodiments;

FIG. 7A is a sectional view of a light-emitting substrate obtained by taking along the section line BB in FIG. 2, in accordance with some embodiments;

FIG. 7B is a sectional view of a light-emitting substrate obtained by taking along the section line BB in FIG. 2, in accordance with some other embodiments;

FIG. 7C is a structural diagram of an adhesive structure in a light-emitting substrate, in accordance with some embodiments;

FIG. 8 is an enlarged view of the region E of the light-emitting substrate in FIG. 7A, in accordance with some embodiments;

FIG. 9 is an enlarged view of the region F of the light-emitting substrate in FIG. 7B, in accordance with some embodiments;

FIG. 10 is a sectional view of a display module, in accordance with some embodiments;

FIG. 11 is another enlarged view of the region F of the light-emitting substrate in FIG. 7B, in accordance with some embodiments;

FIG. 12 is yet another enlarged view of the region F of the light-emitting substrate in FIG. 7B, in accordance with some embodiments; and

FIG. 13 is a plan view of a display apparatus, in accordance with some embodiments.

### DESCRIPTION OF THE INVENTION

The technical solutions in some embodiments of the present disclosure will be clearly and completely described below in conjunction with the accompanying drawings. Obviously, the embodiments to be described are merely some but not all embodiments of the present disclosure. All other embodiments obtained by a person of ordinary skill in the art based on the embodiments of the present disclosure should be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the feature. In the description of the embodiments of the present disclosure, the term “a/the plurality of” means two or more unless otherwise specified.

In the description of some embodiments, the term “coupled” or “connected” and derivatives thereof may be used. The term “connected” should be understood in a broad sense; for example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact with each other. However, the term “coupled” or “communicatively coupled” may also mean that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value, and the acceptable range of deviation is determined, for example, by a person of ordinary skill in the art, considering measurement in question and errors (i.e., limitations of a measurement system) associated with measurement of a particular quantity.

The term such as “parallel”, “perpendicular” or “equal” as used herein includes a stated condition and a condition similar to the stated condition within an acceptable range of deviation, and the acceptable range of deviation is determined, for example, by a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, in a case where a layer or element is referred to as being on another layer or substrate, it may be that the layer or element is directly on the another layer or substrate, or it may be that there is an intermediate layer between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

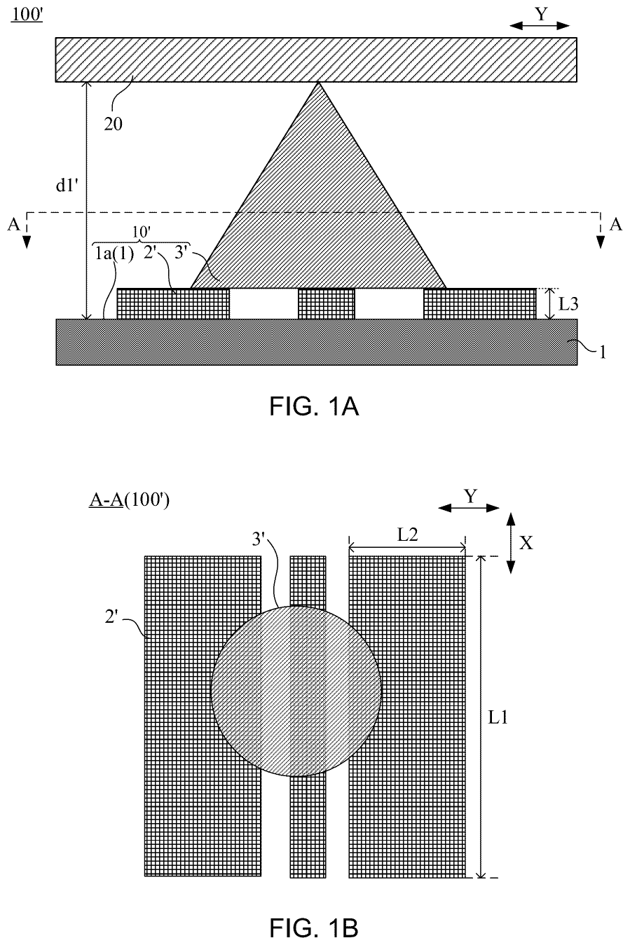

In some examples, as shown in FIG. 1A, a backlight module 100′ includes a light-emitting substrate 10′ and an optical film group 20. The light-emitting substrate 10′ includes a substrate 1, a plurality of signal traces 2′ and a support pillar 3′. The plurality of signal traces 2′ are disposed on a first surface 1a of the substrate 1, and the support pillar 3′ is fixed to the first surface 1a of the substrate 1 by a hot melt adhesive and located between the substrate 1 and the optical film group 20 to ensure that there is a set distance d1′ between the substrate 1 and the optical film group 20. As shown in FIG. 1B, the plurality of signal traces 2′ are arranged, for example, at intervals in a second direction Y, and each signal trace 2′ of the plurality of signal traces 2′ is in a shape of a straight line. Each signal trace 2′ extends, for example, in a first direction X, and the first direction X intersects with the second direction Y. The signal traces 2′ are configured to transmit electrical signals.

As shown in FIGS. 1A and 1B, a dimension of the signal trace 2′ in its extension direction is referred to as a length L1 of the signal trace 2′, a dimension of the signal trace 2′ in a direction perpendicular to its extension direction is referred to as a width L2 of the signal trace 2′, and a dimension of the signal trace 2′ in a direction perpendicular to the first surface 1a of the substrate 1 is referred to as a thickness L3 of the signal trace 2′.

R=(ρ×L1)/(L2×L3), where R is the line resistance of the signal trace 2′ in Ω; ρ is the resistivity of the material of the signal trace 2′ in Ω·m; L1 is the length of the signal trace 2′ in m; L2 is the width of the signal trace 2′ in m; L3 is the thickness of the signal trace 2′ in m; and (L2×L3) is the cross-sectional area of the signal trace 2′ in m².

It will be noted that, reducing the thickness L3 of the signal trace 2′ is one of the main methods to reduce the manufacturing cost of the light-emitting substrate. On the premise that the line resistance R of the signal trace 2′ meets the design requirements, i.e., the line resistance R of the signal trace 2′ is a determinate value, since the resistivity ρ of the material of the signal trace 2′ is constant, and the length L1 of the signal trace 2′ in the light-emitting substrate 10′ of a same size is determinate, the value of (ρ×L1) is determinate. On the premise that the values of R and (ρ×L1) are determinate, it will be understood that while the thickness L3 of the signal trace 2′ is reduced, the width L2 of the signal trace 2′ needs to be increased accordingly. Therefore, as shown in FIGS. 1A and 1B, the arrangement position of the signal trace 2′ will partially overlap with the arrangement position of the support pillar 3′, resulting in the overlap between the support pillar 3′ and the signal trace 2′.

The signal trace 2′ is, for example, directly disposed on the first surface 1a of the substrate 1, and the support pillar 3′ is, for example, glued to the first surface 1a of the substrate 1 by a hot melt adhesive. The support pillar 3′ needs to support the optical film group 20. In a case where the backlight module is applied to a display module, the support pillar 3′ also needs to support a display panel. When the support pillar 3′ is subjected to force, the hot melt adhesive at the bottom of the support pillar 3′ is displaced relative to the set position on the substrate 1, and in this case, if the hot melt adhesive at the bottom of the support pillar 3′ overlaps with the signal trace 2′ on the substrate 1, due to the stickiness of the hot melt adhesive, a portion of the signal trace 2′ overlapping with the hot melt adhesive will be displaced with the hot melt adhesive at the bottom of the support pillar 3′ when the support pillar 3′ is subjected to external force and displaced. As a result, a portion of the signal trace 2′ that is affected by the hot melt adhesive is at risk of peeling off from the surface of the substrate 1.

For example, for a signal trace 2′ with a relatively great width (for instance, the width of the signal trace 2′ is 10 mm, and the dimension, in the width direction of the signal trace 2′, of the portion of the signal trace 2′ overlapping with the hot melt adhesive is 4 mm), after the portion of the signal trace 2′ overlapping with the hot melt adhesive at the bottom of the support pillar 3′ is peeled off from the surface of the substrate 1 with the displacement of the hot melt adhesive, the width L2 of the signal trace 2′ is reduced, which increases the line resistance R of the signal trace 2′. For a signal trace 2′ with a relatively small width (for instance, the width of the signal trace 2′ is 2 mm, and the dimension, in the width direction of the signal trace 2′, of the portion of the signal trace 2′ overlapping with the hot melt adhesive is 1 mm), it will be understood that, when the portion of the signal trace 2′ overlapping with the hot melt adhesive is peeled off from the substrate with the displacement of the hot melt adhesive, a portion of the trace adjacent to the portion overlapping with the hot melt adhesive may also be peeled off at the same time, which may cause the signal trace 2′ to be broken, resulting in failure of electrical signal transmission and poor light emission of the light-emitting substrate.

In light of this, some embodiments of the present disclosure provide a light-emitting substrate 10, a backlight module 100, a display module 1000 and a display apparatus 10000 to overcome the above problems. The light-emitting substrate 10, backlight module 100, display module 1000 and display apparatus 10000 in some embodiments of the present disclosure will be separately introduced below.

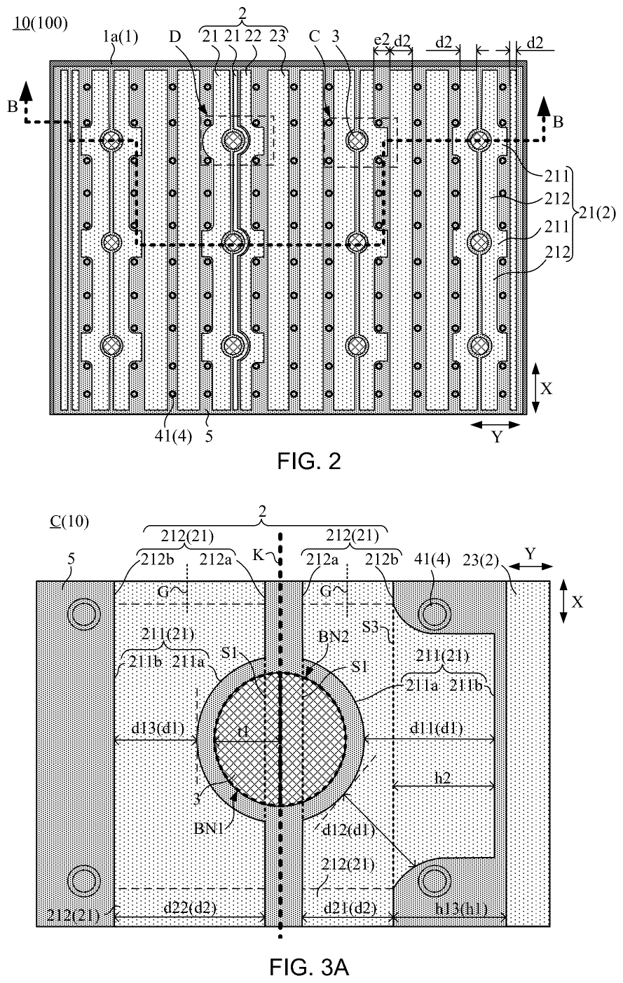

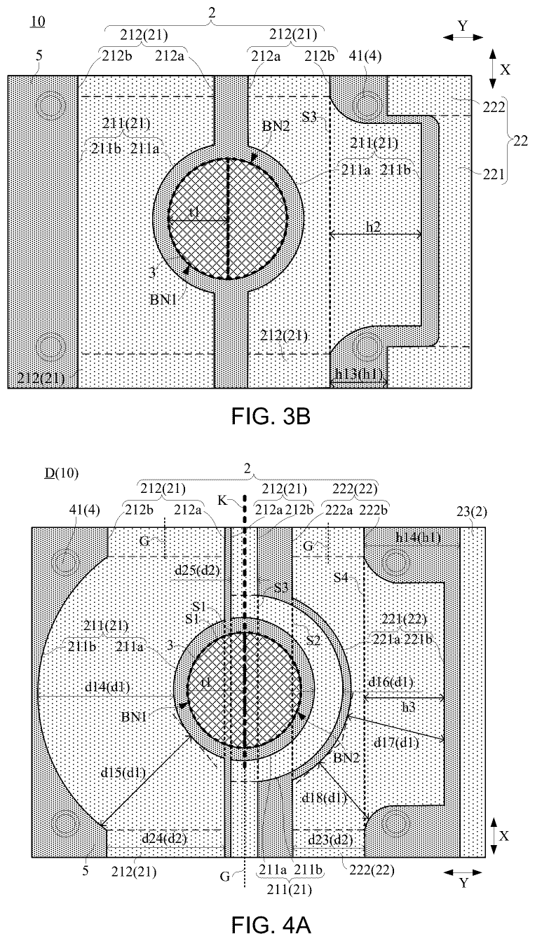

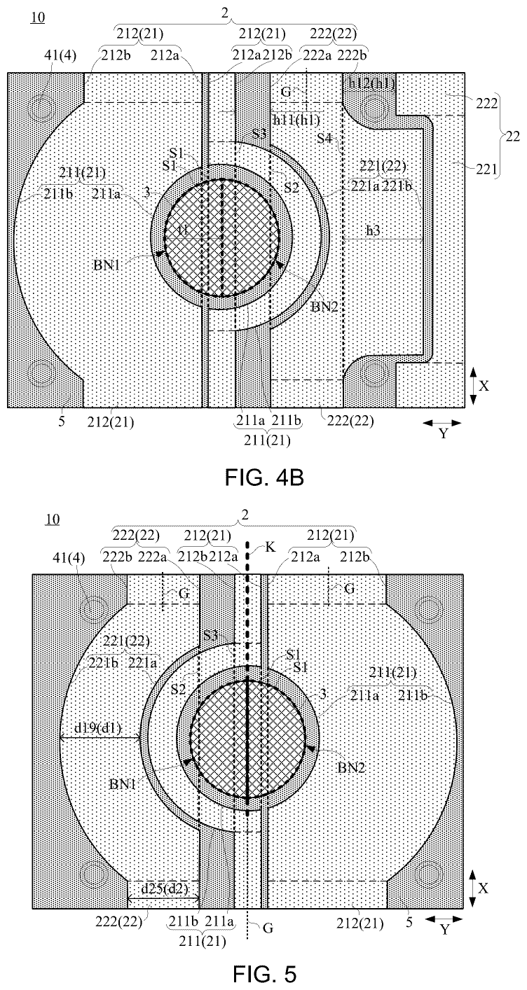

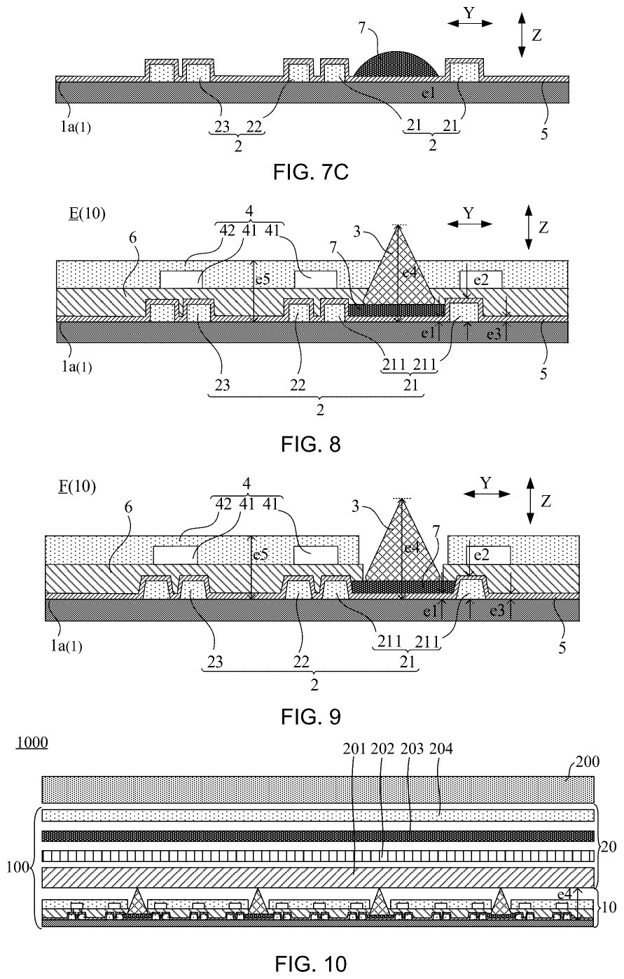

FIG. 2 is a plan view of a light-emitting substrate, in accordance with some embodiments; FIGS. 3A, 3B, 4A and 4B are partial enlarged views of the region C and the region D of the light-emitting substrate in FIG. 2, in accordance with some embodiments; FIGS. 7A and 7B are each a sectional view of a light-emitting substrate obtained by taking along the section line BB in FIG. 2, in accordance with some embodiments; FIG. 7C is a structural diagram of an adhesive structure in a light-emitting substrate in which no support structure is provided; FIG. 8 is an enlarged view of the region E of the light-emitting substrate in FIG. 7A, in accordance with some embodiments; FIGS. 9, 11 and 12 are each an enlarged view of the region F of the light-emitting substrate in FIG. 7B, in accordance with some embodiments; and FIG. 10 is a sectional view of a display module, in accordance with some embodiments.

In order to clearly describe the structural details of the signal lines (e.g., a first signal line 21 and/or a second signal line 22), FIGS. 3A, 4A, 5 and 6 show the enlarged view of portions of the signal lines adjacent to the support structure.

In order to solve the above problems, some embodiments of the present disclosure provide a light-emitting substrate 10, as shown in FIGS. 2, 3A, 4A, 5 and 6, the light-emitting substrate 10 includes a substrate 1, a plurality of signal lines 2, at least one support structure 3, and a device layer 4. The substrate 1 includes a first surface 1a, and the plurality of signal lines 2 are disposed on the first surface 1a of the substrate 1.

The support structure(s) 3 are disposed on the first surface 1a of the substrate 1. The device layer 4 is disposed on a side of the plurality of signal lines 2 away from the first surface 1a of the substrate 1. A ratio of an overlapping area of an orthographic projection of any signal line 2 of the plurality of signal lines 2 on the substrate 1 and an orthographic projection of the support structure 3 on the substrate 1 to an area of the orthographic projection of the support structure 3 on the substrate 1 is greater than or equal to zero and less than or equal to 0.1.

The orthographic projection of any signal line 2 of the plurality of signal lines 2 on the substrate 1 does not overlap with the orthographic projection of the support structure 3 on the substrate 1, or the overlapping area of the two is within a set range.

The signal lines 2 and the support structure(s) 3 are independent from each other. Therefore, in the manufacturing process of the substrate 1, the step of forming the support structure 3 and the step of forming the signal lines 2 may be performed simultaneously or separately one after the other.

In some examples, the step of forming the support structure 3 is after the step of forming the signal lines 2, and when forming the support structure 3, the support structure 3 may partially overlap with the signal lines 2 due to processing errors or other conditions. The ratio of the overlapping area of the orthographic projection of any signal line 2 of the plurality of signal lines 2 on the substrate 1 and the orthographic projection of the support structure 3 on the substrate 1 to the area of the orthographic projection of the support structure 3 on the substrate 1 is greater than or equal to zero and less than or equal to 0.1.

It will be noted that, as long as the overlapping area of the support structure 3 and the signal line 2 is within the set range, even if the support structure 3 overlaps with the signal line 2, due to the relatively small overlapping area, the width of the remaining portion of the signal line 2 excluding the portion overlapping with the support structure 3 can still ensure that the signal line 2 can normally transmit signals, so that the support structure 3 will not affect the signal line 2.

In the above-mentioned light-emitting substrate, the support structure is designed to have no overlap or a very small overlapping area with any signal line adjacent thereto, so that poor bonding between the signal line and the substrate caused by a case that the support structure is disposed on the signal line is avoided.

In some embodiments, the plurality of signal lines are disposed on the first surface. Poor bonding between the signal lines and the substrate means that, the support structure is glued to the first surface by, for example, a hot melt adhesive, when the support structure is displaced by force, the hot melt adhesive is also displaced with the displacement of the support structure due to the fact that the support structure overlaps with the signal line, and the displacement of the hot melt adhesive may push an adjacent signal line, causing a portion of the signal line pushed by the hot melt adhesive to peel off from the surface of the substrate.

Furthermore, for a signal line with a relatively great width, the portion peeled off from the surface of the substrate may break, resulting in a reduction in the width of the signal line and an increase in line resistance, which results in an increase in power consumption of the signal line; for a signal line with a relatively small width, the signal line may break at the position where the signal line is peeled off from the substrate, which results in abnormal signal transmission and abnormal display of the light-emitting substrate.

In some other embodiments, other film layer structures are further included between the plurality of signal lines and the substrate. In this case, the poor bonding between the signal line and the substrate means that, the support structure is glued to the film layer structure between the signal line and the substrate by, for example, a hot melt adhesive, and when the support structure is displaced by force, the hot melt adhesive is also displaced with the displacement of the support structure due to the fact that the support structure overlaps with the signal line, and the displacement of the hot melt adhesive may push an adjacent signal line, causing a portion of the signal line pushed by the hot melt adhesive to peel off from the surface of the film layer structure between the signal line and the substrate.

In some embodiments, the plurality of signal lines 2 include, for example, visible light-emitting diode (VLED) lines and ground (GND) lines; two signal lines 2 adjacent to each support structure 3 are, for example, a VLED line and a GND line.

The specific structure and arrangement of the plurality of signal lines 2 included in the light-emitting substrate 10 are introduced below.

For example, as shown in FIG. 2, the plurality of signal lines 2 included in the light-emitting substrate 10 include, for example, first-type signal lines and second-type signal lines, and each signal line 2 may be divided into a plurality of sub-portions that are sequentially connected end to end.

Each sub-portion of the plurality of sub-portions included in a second-type signal line 23 has a constant extension direction; that is, the sub-portions of the second-type signal line 23 may all be considered to be straight sub-portions.

In some examples, as shown in FIG. 2, each straight sub-portion included in the second-type signal line 23 has a same extension direction, and an orthographic projection of the second-type signal line 23 on the substrate 1 is in a shape of, for example, a rectangle.

In some other examples, the extension directions of the plurality of straight sub-portions included in the second-type signal line are not completely the same. The orthographic projection of the second-type signal line on the substrate may be in a shape of a polyline, such as a shape of “L”.

The first-type signal lines, such as the first signal lines 21 and the second signal lines 22 shown in FIG. 2, are disposed near at least one support structure 3, and the second signal line 22 is further away from the support structure 3 than the first signal line 21 adjacent to the second signal line 22. Meanwhile, the first signal line 21 and the second signal line 22 each as a whole may be substantially considered to extend in the direction X, and the first signal line 21 and the second signal line 22 each includes, for example, a plurality of straight sub-portions and detour sub-portions that are alternately arranged.

As shown in FIGS. 2, 3A and 4A, a detour sub-portion 211 of the first signal line 21 is arranged along a border of a support structure 3, the second signal line 22 is disposed on a side of the first signal line 21 away from the support structure 3, and a detour sub-portion 221 of the second signal line 22 is arranged along a border of the detour sub-portion 211 of the first signal line 21.

It will be noted that, for the case where the light-emitting substrate includes a plurality of support structures 3 and a plurality of signal lines 2 (e.g., the first signal lines 21 and/or the second signal lines 22), what is compared here is the relationship between any support structure, the detour sub-portion of the signal line(s) adjacent to the support structure (e.g., the detour sub-portion 211 of the first signal line 21 and/or the detour sub-portion 221 of the second signal line 22) and the straight sub-portion(s) connected to the detour sub-portion(s) (e.g., the straight sub-portion 212 of the first signal line 21 and/or the straight sub-portion 222 of the second signal line 22). For the structure of the remaining portions of the signal lines, there is no limitation here.

For example, as shown in FIGS. 3A and 4A, an orthographic projection of the support structure 3 on the substrate 1 is divided into a first sub-region BN1 and a second sub-region BN2 by a reference line K extending in the first direction X, and the maximum value of the dimension of the first sub-region BN1 in the second direction Y is equal to the maximum value of the dimension of the second sub-region BN2 in the second direction Y. The first direction X is perpendicular to the second direction Y.

For example, the orthographic projection of the support structure 3 on the substrate 1 is in a shape of a circle, and the reference line K extending in the first direction X may be regarded as a symmetry axis of the orthographic projection of the support structure 3 on the substrate 1. The reference line K divides the orthographic projection of the support structure 3 on the substrate 1 into the semicircular first sub-region BN1 and the semicircular second sub-region BN2. In a case where a symmetry axis G of a straight sub-portion of a signal line 2 is located on a side of the reference line K, a detour sub-portion of the signal line 2 is located on the same side of the reference line K with the symmetry axis G; and in a case where the symmetry axis G of the straight sub-portion of the signal line 2 is colinear with the reference line K, the detour sub-portion of the signal line 2 is located on either side of the reference line K.

In some embodiments, as shown in FIGS. 3A and 4A, the detour sub-portion 211 of the first signal line 21 is located on a side of the support structure 3. The symmetry axis G, extending in the first direction X, of the straight sub-portion 212 of the first signal line 21 is located on a side of the reference line K, and the detour sub-portion 211 of the first signal line 21 and the symmetry axis G of the straight sub-portion 212 of the first signal line 21 are located on the same side of the reference line K.

It will be understood that, in a case where the straight sub-portion 212 of the first signal line 21 as a whole is closer to the first sub-region BN1 (or the second sub-region BN2) than the reference line K, the detour sub-portion 211 of the first signal line 21 detours the support structure 3 from a side of the first sub-region BN1 (or the second sub-region BN2), so as to avoid a situation where the support structure 3 overlaps with the signal line 2.

It will be noted that, the situation where the support structure overlaps with the signal line includes the following situations. The support structure is in direct contact with the signal line, and in this case, when the support structure is displaced, a portion of the signal line overlapping with the support structure is affected by the displacement of the support structure, which causes the signal line to be at risk of being separated from or peeling off from the substrate. Alternatively, the support structure and the signal line are in indirect contact with each other through other structures, i.e., the support structure and the signal line overlap in an orthographic projection direction, in this case, when the support structure is displaced, the portion of the signal line overlapping with the support structure will be affected by the displacement of the support structure through the aforementioned other structures, which causes the signal line to be at risk of being separated from or peeling off from the substrate.

For example, for the two first signal lines 21 shown in FIG. 3A, the straight sub-portion 212 of the first signal line 21 on the left is closer to the first sub-region BN1 than the reference line K, and the symmetry axis G of the straight sub-portion 212 of the first signal line 21 on the left is closer to the first sub-region BN1 than the reference line K. Therefore, the detour sub-portion 211 of the first signal line 21 detours the support structure 3 from a side of the first sub-region BN1 away from the second sub-region BN2 to detour the support structure 3, thereby avoiding the problem of the support structure overlapping with the signal line, ensuring that the signal line 2 can normally transmit electrical signals, and avoiding the abnormal display of the light-emitting substrate due to poor bonding between the signal line 2 and the substrate 1. The straight sub-portion 212 of the first signal line 21 on the right in FIG. 3A is closer to the second sub-region BN2 than the reference line K, and the symmetry axis G of the straight sub-portion 212 of the first signal line 21 on the right is closer to the second sub-region BN2 than the reference line K. Therefore, the detour sub-portion 211 of the first signal line 21 on the right in FIG. 3A detours the support structure 3 from a side of the second sub-region BN2 away from the first sub-region BN1 to avoid the support structure 3, thereby avoiding the problem of the support structure overlapping with the signal line, ensuring that the signal line 2 can normally transmit electrical signals, and avoiding the abnormal display of the light-emitting substrate due to poor bonding between the signal line 2 and the substrate 1.

In some other embodiments, as shown in FIG. 4A, a detour sub-portion 211 of a first signal line 21 is located on a side of the support structure 3. A symmetry axis, extending in the first direction X, of a straight sub-portion 212 of the first signal line 21 coincides with the reference line K, and the detour sub-portion 211 of the first signal line 21 is located on either side of the reference line K.

For example, for the two first signal lines 21 shown in FIG. 4A, the symmetry axis G of the straight sub-portion 212 of the first signal line 21 on the right is collinear with the reference line K. In some examples, the detour sub-portion 211 of the first signal line 21 detours the support structure 3 from a side of the first sub-region BN1 away from the second sub-region BN2. In some other examples, the detour sub-portion 211 of the first signal line 21 detours the support structure 3 from a side of the second sub-region BN2 away from the first sub-region BN1.

It will be understood that, the detour direction of the signal line is determined by the relative position between the reference line and the overlapping portion of the extension path of the straight sub-portion of the signal line proximate to the support structure and the orthographic projection of the support structure on the substrate. The extension path here refers to the original path of the signal line in a case where the signal line does not detour the support structure, such as the portion between the extension line S1 of the inner border 212a and the extension line S3 of the outer border 212b of the straight sub-portion 212 of the first signal line 21 in the middle shown in FIG. 4A.

It will be understood that, the arrangement positions of the plurality of support structures 3 on a side of the light-emitting substrate are determinate. As shown in FIG. 2, the plurality of signal lines 2 each as a whole substantially extends, for example, in the first direction X in a straight line.

It will be noted that, this is merely an example of a possible implementation of the signal lines and is not intended to limit the structure of the signal lines.

In some embodiments, referring to FIGS. 3A to 6, a line connecting inner borders of orthographic projections of two straight sub-portions 212 of a first signal line 21 that are adjacent to a support structure 3 on the substrate 1 divides an orthographic projection of the support structure on the substrate into a first region and a second region. The first region is closer to a detour sub-portion 211 of the first signal line 21 than the second region. An area of the first region is M1. An area of a closed figure formed by the line connecting the inner borders of the orthographic projections of the two straight sub-portions 212 of the first signal line 21 that are adjacent to the support structure 3 on the substrate 1 and an inner border of an orthographic projection of a detour sub-portion 211 between the two straight sub-portions 212 of the first signal line 21 on the substrate 1 is M2. A ratio of M2 to M1 is greater than 1 and less than 1.2.

In some embodiments, as shown in FIGS. 2, 3A, 4A, 5 and 6, the plurality of signal lines 2 include at least one first signal line 21, and an embodiment of the first signal line 21 detouring the support structure is as follows.

The first signal line 21 includes at least one detour sub-portion 211 and at least two straight sub-portions 212, and all detour sub-portions 211 and all straight sub-portions 212 of the first signal line 21 are alternately arranged. The straight sub-portion 212 of the first signal line 21 extends in the first direction X, and includes an inner border 212a and an outer border 212b both extending in the first direction X. An orthographic projection of an extension line S1 of the inner border 212a of the straight sub-portion 212 of the first signal line 21 on the substrate 1 passes through an orthographic projection of a support structure 3 adjacent to the straight sub-portion 212 on the substrate 1; that is, in a case where the first signal line 21 does not include the detour sub-portion 211, the support structure 3 overlaps with the first signal line 21.

As shown in FIGS. 3A and 4A, the detour sub-portion 211 of the first signal line 21 includes an inner border 211a proximate to the reference line K and an outer border 211b away from the reference line K. The inner border 211a of the detour sub-portion 211 of the first signal line 21 is connected to the inner border 212a of the straight sub-portion 212 of the first signal line 21, and the outer border 211b of the detour sub-portion 211 of the first signal line 21 is connected to the outer border 212b of the straight sub-portion 212 of the first signal line 21.

As shown in FIGS. 2, 3A, 4A, 5 and 6, in the second direction Y, the maximum value of a distance between the reference line and the inner border 211a of the detour sub-portion 211 of the first signal line is greater than a distance between the reference line K and the inner border 212a of the straight sub-portion 212 of the first signal line 21; the outer border 211b of the detour sub-portion 211 of the first signal line 21 is located on a side of the support structure 3 in the second direction Y, an orthographic projection of the outer border 211b of the detour sub-portion 211 of the first signal line 21 on the substrate 1 is non-overlapping with the orthographic projection of the support structure 3 on the substrate 1, and a distance between the reference line K and the outer border 211b of the detour sub-portion 211 of the first signal line 21 is greater than a distance between the reference line K and the outer border 212b of the straight sub-portion 212 of the first signal line 21; that is, the outer border 211b of the detour sub-portion 211 of the first signal line 21 is further away from the support structure 3 than the outer border 212b of the straight sub-portion 212 of the first signal line 21. The first direction X is perpendicular to the second direction Y. That is, the detour sub-portion 211 of the first signal line 21 as a whole deviates from the original extension path and toward a side of the support structure 3.

A signal line 2 adjacent to a support structure 3 of the plurality of signal lines 2 is referred to as a first signal line 21, the first signal line 21 includes a detour sub-portion 211 arranged along a border of the support structure 3, and an inner border 211a of the detour sub-portion 211 of the first signal line 21 is arranged, for example, along a border of an orthographic projection of the support structure 3 to which the detour sub-portion 211 is proximate on the substrate 1. As shown in FIGS. 2, 3A, 4A, 5 and 6, the orthographic projection of the support structure 3 on the substrate 1 is in a shape of, for example, a circle; the inner border 211a of the first signal line 21 is in a shape of, for example, an arc; and the inner border 211a of the first signal line 21 does not overlap with the support structure 3.

With such a design, the extension path of the detour sub-portion 211 of the first signal line 2 is not completely consistent with the extension path of the straight sub-portion 212 of the first signal line 21, and the inner border 211a of the detour sub-portion 211 extends along the border of the support structure 3 to detour the support structure 3, so that the support structure 3 does not overlap with the first signal line 21 adjacent thereto, which can prevent the support structure 3 from being disposed on the signal line 2 to avoid the problem that the portion of the signal line 2 overlapping with the support structure 3 is peeled off from the substrate 1 due to the displacement of the support structure 3 caused by force, thereby ensuring that the signal line 2 can normally transmit electrical signals and avoiding the abnormal display of the light-emitting substrate due to the poor bonding between the signal line 2 and the substrate 1.

As shown in FIG. 2, the first signal line 21 as a whole substantially extends in the first direction X, and both ends of the detour sub-portion 211 included in the first signal line 21 are each connected to a straight sub-portion 212. Here, description is made by taking an example in which the extension lines of the outer borders 212b of the straight sub-portions 212 included in the first signal line 21 are collinear, and the extension lines of the inner borders 212a of the straight sub-portions 212 included in the first signal line 21 are collinear.

In some embodiments, the first signal line 21 includes a plurality of detour sub-portions 211 and a plurality of straight sub-portions 212, and the plurality of detour sub-portions 211 and the plurality of straight sub-portions 212 included in the first signal line 21 are alternately arranged. As shown in FIG. 2, the first signal line 21 includes, for example, a straight sub-portion 212, a detour sub-portion 211, another straight sub-portion 212, another detour sub-portion 211, yet another straight sub-portion 212, yet another detour sub-portion 211 and still yet another straight sub-portion 212 that are sequentially connected end to end. The extension lines of the inner borders 212a of the plurality of straight sub-portions 212 included in the first signal line 21 are collinear, and the extension lines of the outer borders 212b of the plurality of straight sub-portions 212 are collinear.

In some other embodiments, the first signal line 21 includes a detour sub-portion 211 and two straight sub-portions 212, and the detour sub-portion 211 and the two straight sub-portions 212 included in the first signal line 21 are alternately arranged. As shown in FIGS. 2, 3A and 4A, the first signal line 21 includes, for example, a straight sub-portion 212, a detour sub-portion 211 and another straight sub-portion 212 that are sequentially connected end to end. The extension lines of the inner borders 212a of the two straight sub-portions 212 of the first signal line 21 are collinear, and the extension lines of the outer borders 212b of the two straight sub-portions 212 are collinear.

It will be understood that, the inner border 211a of the detour sub-portion 211 of the first signal line 21 is connected to an inner border 212a of a straight sub-portion 212 of the first signal line 21, and the outer border 211b of the detour sub-portion 211 of the first signal line 21 is connected to the outer border 212b of the straight sub-portion 212 of the first signal line 21. The connection between the borders refers to that a border (the inner border 211a or outer border 211b) of any detour sub-portion 211 of the first signal line 21 is connected to a border (the inner border 212a or the outer border 212b) of a straight sub-portion 212 connected to the detour sub-portion 211.

In some embodiments, widths d2 of at least two signal lines of the plurality of signal lines 2 are different. For example, as shown in FIG. 2, the widths d2 of at least two signal lines 2 of the plurality of signal lines 2 included in the light-emitting substrate 10 are different.

In some other embodiments, the widths of any two signal lines of the plurality of signal lines included in the light-emitting substrate are the same.

It will be noted that, as shown in FIG. 2, the plurality of signal lines 2 are arranged, for example, in parallel in the second direction Y, and the plurality of signal lines 2 each as a whole substantially extend in the first direction X, and the first direction X intersects with the second direction Y. Here, the comparison of the width d2 of two adjacent signal lines 2 refers to the comparison of the dimension of the straight sub-portion of the two adjacent signal lines 2 in the second direction Y. A first-type signal line (e.g., the first signal line 21 and the second signal line 22 shown in FIG. 2) includes a detour sub-portion, and the width of the signal line is not constant. In some examples, the widths of the straight sub-portion and the detour sub-portion of the signal line are different, and the width of the detour sub-portion of the signal line varies, but the widths of the straight sub-portions of a same signal line are the same or substantially the same. Therefore, the comparison of widths of any two signal lines is the comparison of the widths of the straight sub-portions of the two signal lines.

In some embodiments of the present disclosure, for the signal line, such as the first signal line 21, only the structure of portions proximate to the support structure 3, for example, the portions shown in FIGS. 2, 3A, 4A, 5 and 6, is described, and the structure of other portions of the signal line is not limited.

For example, as shown in FIGS. 3A and 4A, the detour sub-portion 211 of the first signal line 21 is arranged along the border of the orthographic projection of the support structure 3 on the substrate, and the shape of the inner border 211a of the detour sub-portion 211 of the first signal line 21 matches the shape of the border of the orthographic projection of the support structure 3 on the substrate.

In some embodiments, as shown in FIGS. 3A and 4A, the inner border 212a and the outer border 212b of the straight sub-portion 212 of the first signal line 2 are, for example, in a shape of a straight line, and the orthographic projection of the support structure 3 on the substrate is, for example, in a shape of a circle. A portion of the border of the orthographic projection of the support structure 3 on the substrate 1 opposite to the inner border 211a of the detour sub-portion 211 of the first signal line 21 is in a shape of an arc, and the inner border 211a of the detour sub-portion 211 of the first signal line 21 is in a shape of an arc.

With such a design, while ensuring that the extension path of the signal line (e.g., the first signal line 21) detours the region where the support structure is disposed, i.e., the orthographic projection of the support structure on the substrate, the width of the signal line is also ensured, so that the width of the signal line may be greater within an allowable range. It will be understood that, in a case where the length and thickness of the signal line are constant, the greater the width of the signal line, the smaller the line resistance of the signal line, and the smaller the power consumption of the signal line, which is conducive to reducing the power consumption of the light-emitting substrate.

For example, as shown in FIG. 3A, the shape of the outer border 211b of the detour sub-portion 211 of the first signal line 21 is different from the shape of the inner border 211a of the detour sub-portion 211 of the first signal line 21. For the two first signal lines 21 shown in FIG. 3A, the inner border 211a of the detour sub-portion 211 of the first signal line 21 is in a shape of, for example, an arc, and the outer border 211b of the detour sub-portion 211 of the first signal line 21 is in a shape of, for example, a straight line, a pattern of “ [symbol] ”, or a pattern “ [symbol] ”.

In a case where the outer border 211b of the detour sub-portion 211 of the first signal line 21 is in the shape of the pattern “ [symbol] ”, as shown in FIG. 3A, the width d1 (e.g., the dimension d11 or d12 shown in FIG. 3A) of the detour sub-portion 211 of the first signal line 21 is greater than or equal to the width d2 (e.g., the dimension d21 shown in FIG. 3A) of the straight sub-portion 212 of the first signal line 21. With such a design, on the basis that the first signal line 21 detours the support structure 3 to avoid a case that the support structure 3 overlaps with the signal line (e.g., the first signal line 21), the width of the portion (e.g., the detour sub-portion 211 of the first signal line 21) of the first signal line 21 proximate to the support structure 3 is increased, so that the line resistance of the portion of the first signal line 21 proximate to the support structure 3 is reduced, which is conducive to reducing the power consumption of the signal line 2, thereby reducing the power consumption of the light-emitting substrate 10.

For another example, as shown in FIG. 4A, the shape of the outer border 211b of the detour sub-portion 211 of the first signal line 21 is the same as the shape of the inner border 211a of the detour sub-portion 211 of the first signal line 21. For the two first signal lines 21 shown in FIG. 4A, the outer border 211b of the detour sub-portion 211 of the first signal line 21 on the left is in a shape of, for example, an arc, and the inner border 211a of the detour sub-portion 211 of the first signal line 21 on the left is in a shape of, for example, an arc.

With such a design, the width of the detour sub-portion 211 of the first signal line 21 is the same or substantially the same everywhere, so that the overall appearance of the signal line 2 is beautiful; meanwhile, the arc-shaped border is beneficial for the bonding between the signal line 2 and the substrate. Thus, it is difficult for the signal line 2 to be peeled off from the substrate when other components in the light-emitting substrate accidentally collide with the signal line 2, which is conducive to ensuring the reliability of the signal line 2.

It will be understood that, the shapes of the inner border 211a and the outer border 211b of the detour sub-portion 211 of the first signal line 21 may be the same or different, which may be selected according to the actual structure, and may not be limited. In this way, the arrangement is flexible, so that the structure of the first signal line 21 may be applicable to more scenarios.

For example, the widths of two adjacent signal lines may be the same or different, and the widths of each straight sub-portion and each detour sub-portion included in the signal line are not completely the same.

In some examples, as shown in FIGS. 3A and 4A, a dimension d1 of a detour sub-portion 211 of a first signal line 21 in a direction perpendicular to an extension direction of the detour sub-portion 211 is greater than or equal to a dimension d2 of a straight sub-portion 212 of the first signal line 21 in a direction perpendicular to an extension direction of the straight sub-portion 212. It will be noted that the extension direction of the detour sub-portion 211 of the first signal line 21 mentioned here refers to the extension direction of the inner border 211a of the detour sub-portion 211.

For example, the inner border 211a of the detour sub-portion 211 of the first signal line 21 shown in FIG. 3A is arc-shaped, and the extension direction of the inner border 211a of the detour sub-portion 211 refers to an extension direction of a tangent of any point on the inner border 211a of the detour sub-portion 211. A perpendicular line is made along a tangent line of any point on the inner border 211a, and a dimension d12 of the detour sub-portion 211 in a direction along the perpendicular line is the width of the detour sub-portion 211.

For example, for the two first signal lines 21 shown in FIG. 3A, the widths d2 (e.g., the dimensions d21 and d22 shown in FIG. 3A) of the straight sub-portions 212 of the two first signal lines 21 are different. The width d1 (e.g., the dimensions d11 and d12 shown in FIG. 3A) of the detour sub-portion 211 of the first signal line 21 on the right is greater than or equal to the width d2 (e.g., the dimension d21 shown in FIG. 3A) of the straight sub-portion 212 of the first signal line 21.

For another example, for the two first signal lines 21 shown in FIG. 4A, the widths d2 (e.g., the dimensions d25 and d24 shown in FIG. 4A) of the straight sub-portions 212 of the two first signal lines 21 are different. The width d1 (e.g., the dimensions d14 and d15 shown in FIG. 3A) of the detour sub-portion 211 of the first signal line 21 on the left is greater than or equal to the width d2 (e.g., the dimension d24 shown in FIG. 4A) of the straight sub-portion 212 of the first signal line 21. The width d1 (e.g., the dimension d16 shown in FIG. 4A) of the detour sub-portion 211 of the first signal line 21 on the right is equal to the width d2 (e.g., the dimension d25 shown in FIG. 4A) of the straight sub-portion 212 of the right side first signal line 21.

With such a design, the width of the detour portion of the signal line is increased without interfering with other structures of the light-emitting substrate, which reduces the line resistance of the signal line, thereby reducing the power consumption of the signal line and thus reducing the power consumption of the light-emitting substrate.

In some other embodiments, as shown in FIGS. 2, 3A and 3B, the plurality of signal lines 2 include at least one first signal line 21, and another embodiment of the first signal line 21 detouring the support structure is as follows.

The first signal line 21 includes at least two straight sub-portions 212 and at least one detour sub-portion 211, and all the straight sub-portions 212 and all the detour sub-portions 211 of the first signal line 21 are alternately arranged. The straight sub-portion 212 of the first signal line 21 extends in the first direction X, and includes an inner border 212a and an outer border 212b both extending in the first direction X. An orthographic projection of an extension line S1 of the inner border 212a of the straight sub-portion 212 of the first signal line 21 on the substrate 1 passes through the orthographic projection of the support structure 3 on the substrate 1.

The detour sub-portion 211 of the first signal line 21 includes an inner border 211a proximate to the reference line K and an outer border 211b away from the reference line K. The inner border 211a of the detour sub-portion 211 of the first signal line 21 is connected to the inner border 212a of the straight sub-portion 212 of the first signal line 21, and the outer border 211b of the detour sub-portion 211 of the first signal line 21 is connected to the outer border 212b of the straight sub-portion 212 of the first signal line 21.

In the second direction Y, the maximum value of a distance between the reference line K and the inner border 211a of the detour sub-portion 211 of the first signal line 21 is greater than a distance between the reference line K and the inner border 212a of the straight sub-portion 212 of the first signal line 21; the outer border 211b of the detour sub-portion 211 of the first signal line 21 is located on a side of the reference line K in the second direction Y, the outer border 211b of the detour sub-portion 211 of the first signal line 21 is non-overlapping with the orthographic projection of the support structure 3 on the substrate 1, and the outer border 211b of the detour sub-portion 211 of the first signal line 21 is colinear with the outer border 212b of the straight sub-portion 212 of the first signal line 21.

For example, referring to the first signal line 21 on the left in FIG. 3A, the detour sub-portion 211 of the first signal line 21 is a portion remained after a portion of the signal line 2 that may overlap with the support structure 3 is removed, so as to achieve that the signal line detours the support structure 3.

For the beneficial effects of the first signal line 21 adopting this design, reference may be made to the above description, which will not be repeated here.

In some examples, as shown in FIG. 3A, a dimension d1 of a detour sub-portion 211 of a first signal line 21 in a direction perpendicular to the extension direction of the detour sub-portion 211 is less than a dimension d2 of a straight sub-portion 212 of the first signal line 21 perpendicular to the extension direction of the straight sub-portion 212. The dimension of the detour sub-portion 211 of the first signal line 21 in the direction perpendicular to the extension direction of the detour sub-portion 211 is greater than or equal to 100 μm.

For the two first signal lines 21 shown in FIG. 3A, the widths d2 (e.g., the dimensions d21 and d22 shown in FIG. 3A) of the straight sub-portions 212 of the two first signal lines 21 are different. The width d1 (e.g., the dimension d13 shown in FIG. 3A) of the detour sub-portion 211 of the left side first signal line 21 is less than the width d2 (e.g., dimension d22 shown in FIG. 3A) of the straight sub-portion 212 of the first signal line 21.

On the premise that the minimum width d1 (e.g., the dimension d13 shown in FIG. 3A) of the signal line is ensured to meet the line resistance requirement, the outer border of the detour sub-portion of the signal line is, for example, colinear with the outer border of the straight sub-portion connected to the detour sub-portion. With such a design, the overall extension path of the signal line is not changed, and only a portion that may overlap with the support structure is removed from the portion proximate to the support structure.

In this case, the outer borders of multiple sub-portions (straight sub-portions and detour sub-portion(s)) of the signal line are collinear, the widths of the multiple straight sub-portions of the signal line are the same, and the width of the detour sub-portion of the signal line is less than the width of the straight sub-portion of the signal line while the minimum width of the detour sub-portion meets the line resistance requirement for the signal line. It will be understood that, the signal line, for example, adopting the structure of the first signal line 21 on the left in FIG. 3A is applicable to signal lines with a relatively great width, and the minimum width of the detour sub-portion (e.g., the dimension d13 shown in FIG. 3A) is greater than or equal to 100 μm.

For example, as shown in FIGS. 2, 3A, 4A, 5 and 6, the plurality of signal lines 2 include at least two first signal lines 21, and the support structures 3 are surrounded by the detour sub-portions 211 of two adjacent first signal lines 21.

For example, as shown in FIGS. 2, 4A, 5 and 6, the plurality of signal lines 2 include at least one second signal line 22, and the second signal line 22 is at least adjacent to one first signal line 21. The second signal line 22 includes at least two straight sub-portions 222 and at least one detour sub-portion 221, and all straight sub-portions 222 and all detour sub-portions 221 of the second signal line 22 are alternately arranged. The straight sub-portions 222 of the second signal line 22 extend in the first direction X, and the second signal line 22 is further away from the support structure 3 than the detour sub-portion 211 of the first signal line 21 adjacent to the second signal line 22.

A spacing, in the second direction Y, between any two adjacent signal lines 2 of the plurality of signal lines 2 is less than the maximum dimension, in the second direction Y, of the orthographic projection of the support structure 3 on the substrate 1; the dimension, in the second direction Y, of the signal line 2 adjacent to the support structure 3 is less than the maximum dimension, in the second direction Y, of the orthographic projection of the support structure 3 on the substrate 1. It will be understood that, in this case, each support structure 3 is adjacent to at least two signal lines 2.

Here, description is made on the premise that the signal line adjacent to the support structure overlaps with the orthographic projection of the support structure 3 on the substrate 1 in the case where the signal line does not include detour sub-portion(s).

In some embodiments, as shown in FIG. 3A, the orthographic projection of the support structure 3 on the substrate 1 is adjacent to two signal lines 2. In this case, the two signal lines 2 adjacent to the orthographic projection of the support structure 3 on the substrate 1 are each a first signal line 21. The two first signal lines 21 are located, for example, on both sides of the reference line K; for instance, one of the first signal lines 21 is located on a side of the first sub-region BN1 away from the second sub-region BN2, and correspondingly, the other first signal line 21 is located on a side of the second sub-region BN2 away from the first sub-region BN1.

A detour sub-portion 211 of the first signal line 21 located on the side of the first sub-region BN1 away from the second sub-region BN2 extends along the border of the first sub-region BN1, and a detour sub-portion 211 of the other first signal line 21 located on the side of the second sub-region BN2 away from the first sub-region BN1 extends along the border of the second sub-region BN2. The detour sub-portions 211 of the two first signal lines 21 surround the support structure 3.

In some other embodiments, as shown in FIGS. 4A and 5, a support structure 3 is adjacent to three signal lines 2. Among the three signal lines 2, the signal line 2 in the middle is a first signal line 21, and the symmetry axis G of the straight sub-portion 212 of the first signal line 21 in the middle is, for example, colinear with the reference line K. The three signal lines 2 include two first signal lines 21 and one second signal line 22, and the detour sub-portions 211 of the two first signal lines 21 surround the support structure 3.

In some examples, as shown in FIG. 4A, among the three signal lines 2, the detour sub-portion 211 of the first signal line 21 located in the middle detours the support structure 3 from a side of the second sub-region BN2 away from the first sub-region BN1, the detour sub-portion 211 of the first signal line 21 located on the left detours the support structure 3 from a side of the first sub-region BN1 away from the second sub-region BN2, and the detour sub-portions 211 of the two first signal lines 21 surround the support structure 3. The detour sub-portion 221 of the second signal line 22 is arranged along the border of the detour sub-portion 211 of the first signal line 21 located in the middle, and the detour sub-portion 221 of the second signal line 22 surrounds the detour sub-portion 211 of the first signal line 21 adjacent to the second signal line 22.

In the case where there are three signal lines 2 adjacent to the support structure 3, any two adjacent signal lines 2 of the three signal lines 2 are first signal lines 21, the detour sub-portions 211 of the two first signal lines 21 surround the support structure 3, and the remaining signal line 2 is the second signal line 22. The specific structure of the second signal line will be introduced below.

For example, as shown in FIGS. 4A and 5, the detour sub-portion 221 of the second signal line 22 is arranged along the border of the detour sub-portion 211 of the first signal line 21 adjacent to the second signal line 22. The straight sub-portion 222 of the second signal line 22 includes an inner border 222a and an outer border 222b both extending in the first direction X. The detour sub-portion 221 of the second signal line 22 includes an inner border 221a proximate to the first signal line 21 adjacent to the second signal line 22 and an outer border 221b away from the first signal line 21 adjacent the second signal line 22.

The inner border 221a of the detour sub-portion 221 of the second signal line 22 is connected to the inner border 222a of the straight sub-portion 222 of the second signal line 22, and the outer border 221b of the detour sub-portion 221 of the second signal line 22 is connected to the outer border 222b of the straight sub-portion 222 of the second signal line 22. The shape of the inner border 221a of the detour sub-portion 221 of the second signal line 22 is the same as the shape of the outer border 211b of the detour sub-portion 211 of the first signal line 21 adjacent to the second signal line 22.

For the beneficial effects and correspondence between the inner border 221a of the detour sub-portion 221 of the second signal line 22 and the outer border 211b of the detour sub-portion 211 of the first signal line 21 adjacent to the second signal line 22, reference may be made to the aforementioned description of the correspondence between the inner border 211a of the detour sub-portion 211 of the first signal line and the border of the orthographic projection of the support structure 3 on the substrate 1, which will not be elaborated here.

In some examples, as shown in FIG. 4A, the shape of the outer border 221b of the detour sub-portion 221 of the second signal line 22 is different from the shape of the inner border 221a of the detour sub-portion 221 of the second signal line 22.

In some other examples, as shown in FIG. 5, the shape of the outer border 221b of the detour sub-portion 221 of the second signal line 22 is the same as the shape of the inner border 221a of the detour sub-portion 221 of the second signal line 22.

For the beneficial effects and correspondence between the inner border 221a and the outer border 221b of the detour sub-portion 221 of the second signal line 22, reference may be made to the aforementioned description of the correspondence between the inner border 211a and the outer border 211b of the detour sub-portion 211 of the first signal line 21, which will not be elaborated here.

In some embodiments, as shown in FIGS. 4A and 5, a dimension d1 (e.g., the dimensions d17 and d18 shown in FIG. 4A, and the dimension d19 shown in FIG. 5) of the detour sub-portion 221 of the second signal line 22 in a direction perpendicular to the extension direction of the detour sub-portion 221 is greater than or equal to a dimension d2 (e.g., the dimension d23 shown in FIG. 4A, and the dimension d25 shown in FIG. 5) of the straight sub-portion 222 of the second signal line 22 in the direction perpendicular to the extension direction of the straight sub-portion 222.

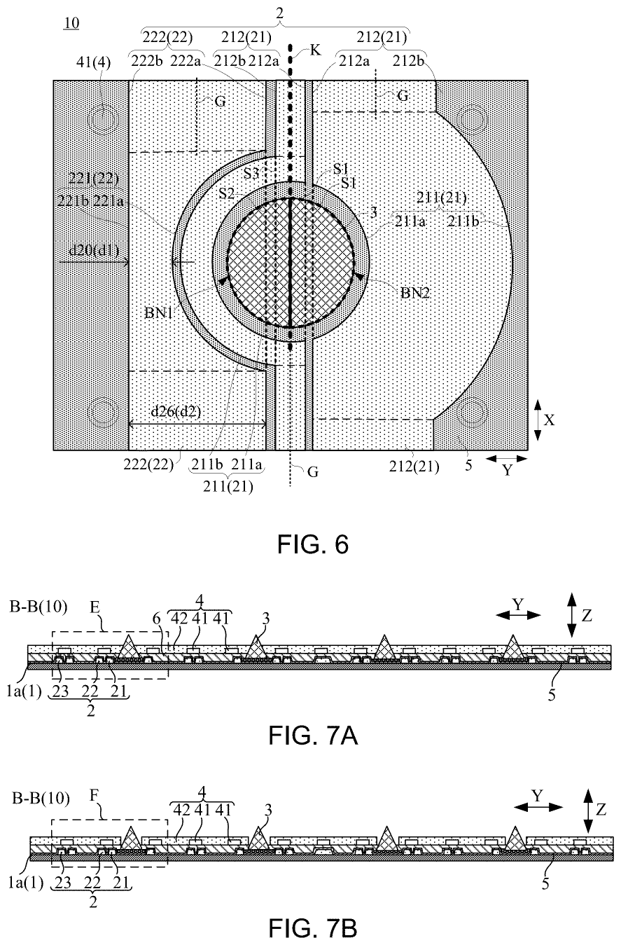

In some other embodiments, as shown in FIG. 6, the dimension d1 (e.g., the dimension d20 shown in FIG. 6) of the detour sub-portion 221 of the second signal line 22 in the direction perpendicular to the extension direction of the detour sub-portion 221 is less than the dimension d2 (e.g., the dimension d26 shown in FIG. 6) of the straight sub-portion 222 of the second signal line 22 in the direction perpendicular to the extension direction of the straight sub-portion 222.

For the arrangement and beneficial effects of the second signal line 22, reference may be made to the aforementioned description of the first signal line 21 and the second signal line 22, which will not be elaborated here.

For example, as shown in FIGS. 3B, 4A and 4B, at least one second signal line 22 is disposed on a side of the first signal line 21 away from the support structure 3.

In some embodiments, as shown in FIG. 4A, a second signal line 22 is disposed on a side of the first signal line 21 away from the support structure 3.

In some other embodiments, as shown in FIGS. 3B and 4B, a plurality of second signal lines 22 are disposed on a side of the first signal line 21 away from the support structure 3.

For example, as shown in FIG. 2, a plurality of signal lines 2 are arranged in parallel in the second direction Y, each signal line 2 extends substantially in the first direction X, and two adjacent signal lines 2 have a spacing therebetween in the second direction Y. The spacing between any two adjacent signal lines of the plurality of signal lines is the same, or the spacing between any two adjacent signal lines of the plurality of signal lines is not completely the same.

It will be noted that, the first-type signal line includes straight sub-portions and detour sub-portion(s), the second-type signal line includes multiple straight sub-portions, and the spacing between two adjacent signal lines mentioned here refers to the distance between the straight sub-portions of the signal lines. Here, description is made by taking an example in which the extension directions of the straight sub-portions included in the first-type signal lines and the straight sub-portions included in the second-type signal lines are the same. In a case where a signal line is a first-type signal line and another signal line adjacent to the first-type signal line is also a first-type signal line, the spacing between the two signal lines refers to the distance between the straight sub-portions of the two first-type signal lines. In a case where a signal line is a first-type signal line and another signal line adjacent to the first-type signal line is a second-type signal line, the spacing between the two signal lines refers to the distance between the straight sub-portion of the first-type signal line and the second-type signal line.

As shown in FIG. 3A, the maximum dimension, in the second direction Y, of the orthographic projection of the support structure 3 on the substrate Y is, for example, 2 times t1, and half of the maximum dimension, in the second direction Y, of the orthographic projection of the support structure 3 on the substrate is t1. The following is discussed under a situation where any two adjacent signal lines of the plurality of signal lines are located on the same side of a support structure.

A spacing h1 (e.g., the dimensions h11 and h12 shown in FIG. 4B) between any two adjacent signal lines of the plurality of signal lines is greater than zero and less than t1. In some embodiments, as shown in FIG. 4B, in a case where one of the two signal lines 2 is a first signal line 21, the other signal line 2 is a second signal line 22. Correspondingly, in a case where one of the two signal lines 2 is a second signal line 22, the other signal line 2 is a first signal line 21 or a second signal line 22. This is because if the spacing between two signal lines is too small, for example, less than t1, then in a case where one of the two signal lines (referred to as a 1 st signal line) is a first-type signal line, the other signal line (referred to as a 2nd signal line) must also be a first-type signal line, otherwise the detour sub-portion of the first signal line will overlap with the second signal line.

In some other embodiments, as shown in FIGS. 3A and 3B, in a case where the spacing h1 (e.g., the dimension h13 shown in FIGS. 3A and 3B) between any two adjacent signal lines 2 of the plurality of signal lines 2 is greater than t1, if one of the two signal lines 2 is a first signal line 21, the other signal line may be a first-type signal line or a second-type signal line 23, which may be determined as follows. As shown in FIG. 3A, if the spacing h13 between the straight sub-portion 212 of the first signal line 21 and the other signal line 2 is greater than the maximum distance (e.g., the dimension h2 shown in FIG. 3A) in the second direction Y between the outer border 211b of the detour sub-portion 211 of the first signal line 21 and the extension line S3 of the outer border 212b of the straight sub-portion 212 of the first signal line 21, then the other signal line 2 is a second-type signal line 23; that is, the spacing h13 is great enough to allow the other signal line to avoid the detour sub-portion of the first signal line such that the two signal lines do not overlap. Otherwise, as shown in FIG. 3B, the other signal line is a second signal line 22.

In some other embodiments, as shown in FIGS. 4A and 4B, in a case where the spacing h1 (e.g., the dimension h14 shown in FIG. 4A) between any two adjacent signal lines 2 of the plurality of signal lines 2 is greater than t1, if one of the two signal lines 2 is a second signal line 22, the other signal line may be a second signal line 22 or a second-type signal line 23, which may be determined as follows. As shown in FIG. 4A, if the spacing h14 between the straight sub-portion 222 of the second signal line 22 and the other signal line 2 is greater than the maximum distance (e.g., the dimension h3 shown in FIG. 4A) in the second direction Y between the outer border 221b of the detour sub-portion 221 of the second signal line 22 and the extension line S4 of the outer border 222b of the straight sub-portion 222 of the second signal line 22, then the other signal line is a second-type signal line 23; that is, the spacing h14 is great enough to allow the other signal line to avoid the detour sub-portion of the second signal line such that the two signal lines do not overlap; alternatively, as shown in FIG. 4B, the spacing h1 (e.g., the dimension h12 shown in FIG. 4B) between the straight sub-portion 222 of the second signal line 22 and the other signal line 2 is less than the maximum distance (e.g., the dimension h3 shown in FIGS. 4A and 4B) in the second direction Y between the outer border 221b of the detour sub-portion 221 of the second signal line 22 and the extension line S4 of the outer border 222b of the straight sub-portion 222 of the second signal line 22, and in this case, the other signal line is also a second signal line 22.

For example, as shown in FIGS. 7A, 7B, 8 and 9, the light-emitting substrate 10 further includes an insulating layer 5 disposed on a side of the plurality of signal lines 2 away from the first surface 1a of the substrate 1, and the insulating layer 5 covers the plurality of signal lines 2. The insulating layer 5 is located between the plurality of signal lines 2 and the support structures 3, and an orthographic projection of the insulating layer 5 on the substrate 1 overlaps with an orthographic projection of the support structure 3 on the substrate.

As shown in FIGS. 8 and 9, in a direction perpendicular to the first surface 1a of the substrate 1, a distance e1 between the first surface 1a of the substrate 1 and a surface of a portion of the insulating layer 5 located between the support structure 3 and the substrate 1 is less than a distance e2 between the first surface 1a of the substrate 1 and a surface of a portion of the insulating layer 5 covering the plurality of signal lines 2.

As shown in FIGS. 8 and 9, a distance e3 between the substrate 1 and a surface of the remaining portion of the insulating layer 5 except the portion located between the support structure 3 and the substrate 1 and the portion covering the plurality of signal lines 2 is the same or substantially the same as the distance e1 between the first surface 1a of the substrate 1 and the surface of the portion of the insulating layer 5 located between the support structure 3 and the substrate 1.

In some embodiments, two signal lines 2 adjacent to a support structure 3 surround the support structure 3. For example, referring to FIGS. 2 to 9, orthographic projections of the detour sub-portions 211 of the two adjacent first signal lines 21 on the substrate 1 surround the orthographic projection of the support structure 3 on the substrate 1. As shown in FIGS. 8 and 9, since the distance e1 is less than the distance e2, a recess is formed in a region corresponding to the orthographic projection of the support structure 3 on the substrate 1, and the bottom of the support structure 3 is disposed in the recess.

It will be understood that, since the support structure 3 is non-overlapping with the signal lines 2, and the two signal lines (e.g., the detour sub-portions 211 of the first signal lines 21) adjacent to the support structure 3 surround the support structure 3, the film thickness (e.g., the thickness of the film layer located between the support structure and the substrate, such as the dimension e1 shown in FIGS. 8 and 9) of the region where the support structure 3 are disposed is less than the film thickness (e.g., the dimension e2 shown in FIGS. 8 and 9) of the region adjacent to the support structure 3.

In this way, in a case where the support structure 3 is disposed on the substrate 1, the support structure 3 is disposed in the recess, and this design helps to position the support structure 3. Meanwhile, since the distance between the substrate 1 and the surface of the portion of the insulating layer 5 covering the signal lines 2 is different from the distance between the substrate 1 and the surface of the portion of the insulating layer 5 located between the portions, that are opposite to each other, of the support structure 3 and the substrate 1, in a case where the support structure 3 is disposed, an end of the support structure 3 is disposed in the recess, so that the support structure 3 will not be disposed on the signal line 2, so as to avoid the case that the support structure 3 overlaps with the signal line 2.

In some other embodiments, as shown in FIGS. 8 and 9, the distance e3 between the substrate 1 and the surface of the remaining portion of the insulating layer 5 except the portion located between the support structure 3 and the substrate 1 and the portion covering the plurality of signal lines 2 is less than or equal to the distance e2 between the first surface 1a of the substrate 1 and the surface of the portion of the insulating layer 5 covering the plurality of signal lines 2.

For example, as shown in FIGS. 7A, 7B, 8, 9 and 10, a distance e4 between the first surface 1a of the substrate 1 and an end of the support structure 3 away from the substrate 1 is greater than a distance e5 between the first surface 1a of the substrate 1 and a surface of the device layer 4 away from the substrate 1.

As shown in FIGS. 8, 9 and 10, in a case where the light-emitting substrate 10 is applied to the backlight module 100, due to the provision of the support structure 3, it is possible to ensure a set distance between the device layer 4 and the optical film group 20, so that a plurality of light-emitting devices 41 included in the device layer 4 can have a set light-mixing distance to eliminate lamp shadows.

For example, as shown in FIGS. 2, 7A, 7B, 8, 9 and 10, the device layer 4 of the light-emitting substrate 10 includes a plurality of light-emitting devices 41 and a plurality of light-emitting driving circuits. The plurality of light-emitting driving circuits are configured to drive the plurality of light-emitting devices 41 to emit light.

Each light-emitting driving circuit drives and controls one, two or more light-emitting devices 41 to emit light. For example, each light-emitting driving circuit drives and controls two light-emitting devices 41, three light-emitting devices 41, four light-emitting devices 41, or six light-emitting devices 41, which is not limited here. At least two light-emitting devices 41 controlled by a same light-emitting driving circuit are connected to each other in series. The driving circuit is, for example, a micro integrated circuit, or a pixel circuit consists of a plurality of thin film transistors connected to each other.

In some embodiments, the light-emitting substrate further includes other elements, such as a sensor chip, and the sensor chip may be a photosensitive sensor chip, a thermal sensor chip, or the like.

In some examples, the pin of the light-emitting driving circuit in the device layer 4 is electrically connected to the signal line 2, or the pin of the light-emitting device 41 is electrically connected to the signal line 2 (e.g., the VLED line).

For example, the light-emitting devices 41 include but are not limited to mini LEDs and micro light-emitting devices (micro LEDs).

The grain size of mini LED and micro LED is small, which may greatly reduce the light-mixing distance of adjacent LED lamp beads. Thus, the light-emitting substrate has the advantages such as local dimming, high color rendering and high contrast; furthermore, it may be possible to further make the light-emitting substrate thin and light, and energy-saving, causing the application of the light-emitting substrate including mini LEDs or micro LEDs to be flexible. In addition, in comparison with organic light-emitting diodes (OLEDs), the light-emitting substrate including mini LEDs or micro LEDs has lower cost, longer service life and lower risk of screen burn-in.

For example, the substrate 1 is a flexible substrate. The substrate 1 is, for example, any of a polyimide (PI) base film, an FR-4 printed circuit board (PCB), a flexible PCB, a metal core PCB and a metal copper clad lamination (MCCL).

For another example, the substrate 1 is a rigid substrate. The substrate 1 is made of, for example, glass, quartz, plastic, a ceramic material such as silicon nitride, aluminum nitride or aluminum oxide, a metal or a metal compound.

It will be understood that the above materials of the substrate 1 are merely examples of possible implementations, and the substrate 1 includes but is not limited to the above examples.

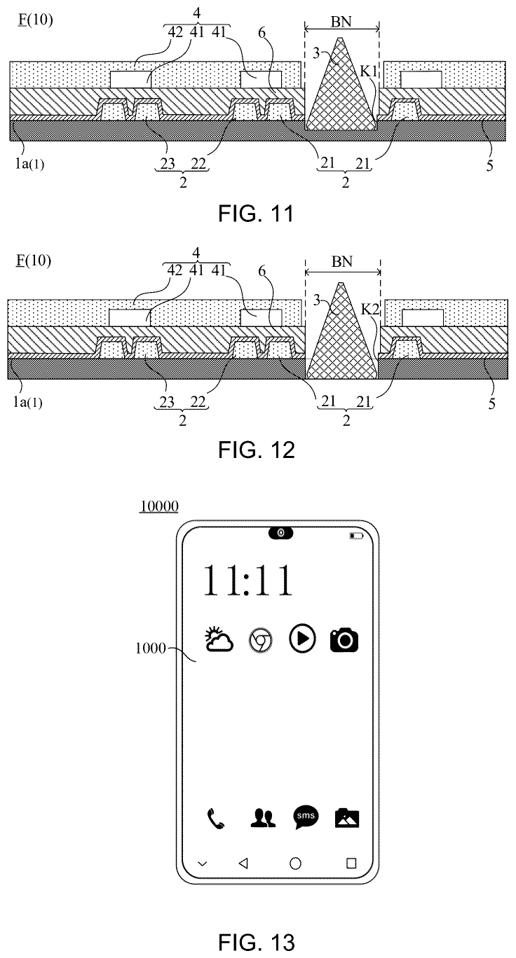

Referring to FIGS. 11 and 12, a region covered by the orthographic projection of the support structure 3 on the substrate 1 is a support region BN; that is, the support region BN is the target arrangement region of the support structure 3.

In some embodiments, the substrate 1 is, for example, a glass substrate, and in this case, forming holes in the surface of the substrate 1 will affect the strength of the glass substrate, resulting in a reduction in the strength of the glass substrate and the occurrence of defects such as cracks. In such case, the support structures 3 are disposed on the first surface 1a of the substrate 1 by an adhesive structure; for example, an end of the support structure 3 is disposed on the first surface 1a of the substrate 1 by an adhesive.

In some other embodiments, the substrate 1 is, for example, a PI base film. Since the PI base film is thin and its performance will be affected by forming holes in the PI base film, for the substrate 1 of PI base film, the support structure 3 is also disposed on the first surface 1a of the substrate 1 by an adhesive structure.

For example, the adhesive structure 7 is an adhesive such as glue, double-sided tape, or a hot melt adhesive. It will be understood that, what is introduced here is merely an example of a possible implementation of the adhesive structure 7, but not a limitation on the adhesive structure 7, as long as the adhesive structure 7 is capable of achieving the fixation of the support structure 3.

Further, an orthographic projection of an adhesive structure 7 on the substrate 1 overlaps or substantially overlaps with an orthographic projection of a support structure 3 corresponding to the adhesive structure 7 on the substrate 1. It will be understood that, in a case where the adhesive structure 7 is a hot melt adhesive, as shown in FIGS. 7C and 8, firstly, the hot melt adhesive is disposed in the target arrangement region of the support structure 3, and then the support structure 3 is disposed on a side of the hot melt adhesive away from the substrate 1. The hot melt adhesive will deform under pressure, and the dimension of the hot melt adhesive in the direction Z, as is shown in FIG. 7C, will decrease, while the dimension of the hot melt adhesive in the direction Y will increase. As shown in FIG. 8, in the direction Y, the dimension of the hot melt adhesive is, for example, slightly greater than the dimension of an end of the support structure 3 proximate to the hot melt adhesive, but the hot melt adhesive will not overlap with the signal line.

As shown in FIGS. 2, 7A, 7B, 7C, 8, 9, 11 and 12, in a case where the support structure 3 is disposed, firstly, an adhesive structure 7 is disposed in the target arrangement region of the support structure 3, and then the support structure 3 is disposed on a side of the adhesive structure 7 away from the substrate 1, so that the support structure 3 is disposed in the set region (i.e., the target arrangement region of the support structure 3) by the adhesive structure 7.

The adhesive structure 7 is, for example, a hot melt adhesive. The hot melt adhesive is solid at a room temperature (e.g., the room temperature is less than or equal to 30° C.), and when the temperature of the hot melt adhesive is maintained within a certain range (e.g., from 65° C. to 135° C.), the hot melt adhesive has a certain fluidity. In a case where the support structure 3 is disposed, firstly, the heated hot melt adhesive with a certain fluidity is disposed in the set region. It will be understood that, to ensure that the support structure 3 is effectively fixed at a position, when the support structure 3 is disposed on the side of the hot melt adhesive away from the substrate 1, the amount of hot melt adhesive needs to be kept within a certain range, and the support structure 3 is pressed toward a direction proximate to the substrate 1 to make the hot melt adhesive to be closely adhered to the support structure 3. If there is too little amount of hot melt adhesive, the adhesion of the support structure 3 is unstable, and if there is too much amount of hot melt adhesive, the problem that the hot melt adhesive between the support structure 3 and the substrate 1 overflows outside of the set region due to the pressure from the support structure 3 occurs.

After the support structure 3 is disposed on the side of the hot melt adhesive away from the substrate 1, the temperature of the hot melt adhesive gradually decreases at the room temperature until the hot melt adhesive solidifies, and thus the support structure 3 is fixed.

It will be understood that, in the case where the hot melt adhesive overflows outside of the set region, the hot melt adhesive overflowing outside of the set region is exposed to the outside after solidification. The expression of “exposed to the outside” here means that, an orthographic projection of the hot melt adhesive overflowing outside of the set region on the substrate overlaps with the orthographic projection of the support structure on the substrate; that is, the support structure 3 partially overlaps with the hot melt adhesive. It will be understood that, the hot melt adhesive overflowing outside of the set region is an undesigned structure, the presence of which brings an unexpected structure on the surface structure of the light-emitting substrate, resulting in appearance defects of the light-emitting substrate.

Furthermore, the hot melt adhesive is generally transparent, but in the case where the hot melt adhesive overflows outside of the set region, the distance between the hot melt adhesive overflowing outside of the set region and the light-emitting device 41 is reduced compared to a set distance. The heat generated during the operation of the light-emitting device 41 will cause the hot melt adhesive to change color due to heat; for example, the hot melt adhesive turns yellow when heated, and in comparison with white, the reflectivity of yellow to light is reduced, so that the luminous efficiency of the device layer 4 is reduced compared to a set value, resulting in poor optical properties of the light-emitting substrate.

In some embodiments, referring to FIGS. 3A to 6, the signal line 2 adjacent to the support structure 3 is set to be a first-type signal line, and the first-type signal line is, for example, a first signal line 21; referring to FIGS. 8, 9, 11 and 12, e1<e2, and the bottom of the support structure 3 is disposed in the recess formed by the detour sub-portions 211 of two adjacent first signal lines 21. It will be understood that, with such a design, when the support structure 3 is disposed, the hot melt adhesive tends to overflow outside of the set region due to the pressure from the support structure 3, and will be blocked by the detour sub-portions 211 of the first signal lines 21, which ensures that the hot melt adhesive is within the region surrounded by the detour sub-portions 211 of the two adjacent first signal lines 21, thereby preventing the hot melt adhesive from overflowing outside of the set region, and avoiding the appearance defects and poor optical properties of the light-emitting substrate.

As shown in FIGS. 8, 9, 11 and 12, the detour sub-portions 211 of the two first signal lines 21 adjacent to the support structure 3 surround the support structure 3 and form a recess in the arrangement region of the support structure 3. In comparison with a situation of a wide area of overflowing hot melt adhesive caused by the fact that the straight-shaped signal lines can block the overflow of the hot melt adhesive only in a direction perpendicular to the extension direction of the signal lines, and the overflowing hot melt adhesive will not be blocked in the extension direction of the signal lines, when the support structure 3 is disposed in the recess formed by the detour sub-portions 211 of the two adjacent first signal lines 21, as shown in FIGS. 3A, 4A, 5 and 6, the detour sub-portions 211 of the first signal lines 21 can block the overflow of the hot melt adhesive in all directions, which may effectively prevent the hot melt adhesive from overflowing outside of the set region.

In some other embodiments, as shown in FIG. 11, the substrate 1 is, for example, a metal substrate or a plastic substrate. In this case, when forming holes in the surface of the substrate 1, defects such as cracks are less likely to occur on the surface of the substrate, and in such case, the support region BN is provided with a blind hole K1 therein, and an end of the support structure 3 is disposed in the blind hole K1.

In yet some other embodiments, as shown in FIG. 12, the substrate 1 is, for example, a metal substrate or a plastic substrate. In this case, when forming holes in the surface of the substrate 1, defects such as cracks are less likely to occur on the surface of the substrate, and in such case, a through hole K2 penetrating through the substrate 1 in a direction perpendicular to the first surface 1a of the substrate 1 is provided in the support region BN, and an end of the support structure 3 is disposed in the through hole K2.

It will be understood that, no matter whether the substrate is made of a rigid material or a flexible material, and a hole (e.g., the blind hole K1 shown in FIG. 11 or the through hole K2 shown in FIG. 12) is formed in the substrate to connect to the support structure 3, which are all applicable to the structure and arrangement of the first-type signal lines (e.g., the first signal line 21 and/or the second signal line 22 shown in FIGS. 2 to 6).

For example, as shown in FIGS. 2 to 6, the orthographic projection of the support region BN on the substrate 1 is in a shape of a circle, an ellipse or a polygon.

As shown in FIG. 10, in a case where the light-emitting substrate 10 is applied to the backlight module 100, an end of the support structure 3 is connected to the first surface 1a of the substrate 1, and the other end of the support structure 3 abuts against the optical film group 20. The support structure 3 is configured to provide a set distance between the device layer 4 and the optical film group 20 such that the plurality of light-emitting devices 41 included in the device layer 4 can have a set light-mixing distance, thereby eliminating lamp shadows and ensuring the light-mixing effect of the backlight module 100.

In some embodiments, the support structure 3 is in a shape of a pillar, and is configured to support the optical film group 20 in the backlight module 100 to keep the set distance between the optical film group 20 and the device layer 4.

Further, as shown in FIG. 10, the support structure 3 may be a pyramid or a prism with an end larger than the other end, and the larger end of the support structure 3 is disposed on a side proximate to the substrate 1. In comparison with a design adopting a prism or a cylindrical support structure, with the above design in FIG. 10, the support structure may block less light emitted by the device layer 4, so that the support structure 3 will not have bad effects on the light-emitting effect of the light-emitting substrate 10 while ensures that the backlight module 100 has a set light-mixing distance.

It will be noted that, this is merely an example of a possible implementation of the support structure, and is not intended to be a limitation on the support structure.

For example, the colour of the support structure 3 includes but is not limited to white.

White has good light-reflecting properties, which allows the light emitted by the device layer 4 to be reflected again and emitted even if the light is blocked by the support structure 3, thereby reducing the influence of the support structure 3 on the light-emitting effect of the device layer 4.

In some other embodiments, the support structure 3 is made of glass, transparent plastic, or the like, so that the support structure 3 has good light transmittance. Thus, the light emitted by the light-emitting devices 41 in the device layer 4 will not be blocked by the support structure 3, so that the light output rate is relatively high, and the light-emitting effect of the light-emitting substrate 10 is improved.

For example, as shown in FIGS. 8 and 9, a reflective layer 6 is provided on a side of the insulating layer 5 away from the substrate 1, and the device layer 4 is disposed on a side of the reflective layer 6 away from the substrate 1.

In some embodiments, the reflective layer is, for example, a white ink layer.

The reflective layer 6 includes a plurality of borders, and the first surface 1a of the substrate 1 includes a plurality of borders. As shown in FIGS. 2 to 10, at least a part of the borders of the reflective layer 6 coincides with at least a part of the borders of the substrate 1. That is, the outermost border of the orthographic projection of the reflective layer 6 on the substrate 1 coincides with or substantially coincides with the surface of the substrate.

In some embodiments, the orthographic projections of the first signal lines 21 and the second signal lines 22 included in the plurality of signal lines 2 on the substrate 1 do not overlap with the orthographic projections of the plurality of light-emitting devices 41 included in the device layer 4 on the substrate 1.

For example, there is no overlapping portion between the orthographic projections of the first signal lines 21 and the second signal lines 22 included in the plurality of signal lines 2 on the substrate 1 and the orthographic projections of the plurality of light-emitting devices 41 included in the device layer 4 on the substrate 1. That is, the first signal lines 21 and the second signal lines 22 included in the plurality of signal lines 2 and the plurality of light-emitting devices 41 included in the device layer 4 do not have portions that overlap with each other.

For example, as shown in FIGS. 7A, 7B, 8, 9, 10, 11 and 12, the device layer 4 further includes a protective structure 42, and the protective structure 42 is of a layered structure and covers the plurality of light-emitting devices 41. It will be understood that the protective structure 42 is made of a transparent material, such as transparent silicone.

In some embodiments, as shown in FIG. 8, the protective structure 42 surrounds a portion of the support structure 3 proximate to the substrate 1.

The protective structure 42 can protect the plurality of light-emitting devices 41 to prevent the plurality of light-emitting devices 41 from being damaged during a process after the light-emitting devices 41 are formed.

It will be understood that, with such a design, the support structure 3 needs to be disposed in the support region BN first, and then the protective structure 42 is provided.

In this way, the protective structure 42 can not only protect the plurality of light-emitting devices 41, but also limit the position of the support structure 3 to prevent the support structure 3 from moving to interfere with the remaining structures of the light-emitting substrate 10.

In some other embodiments, as shown in FIGS. 10, 11 and 12, the protective structure 42 includes a plurality of openings. The support structure 3 is exposed outside of the protective structure 42 through the opening, and the support structure 3 is not in contact with the protective structure 42.

With such a design, the plurality of openings included in the protective structure 42 increases the surface area of the protective structure 42, which is conducive to heat dissipation of the device layer 4 and helps to prolong the service life of the light-emitting devices 41.

It will be understood that, in some embodiments, the protective structure may be of a discrete structure that separately covers and protects the plurality of light-emitting devices.

Some embodiments of the present disclosure provide a backlight module 100. As shown in FIGS. 7A, 7B and 10, the backlight module 100 includes the light-emitting substrate 10 provided in any of the above embodiments, and an optical film group 20 disposed on a side of the device layer 4 of the light-emitting substrate 10 away from the substrate 1.

There is a set distance e4 between the device layer 4 of the light-emitting substrate 10 and the optical film group 20, and an end of the support structure 3 of the light-emitting substrate 10 away from the substrate 1 abuts against the optical film group 20.

The backlight module 100 has the same beneficial effects as the aforementioned light-emitting substrate 10, which will not be repeated here.

Some embodiments of the present disclosure provide a display module 1000. As shown in FIG. 10, the display module 1000 includes the backlight module 100 provided in the above embodiments and a display panel 200. The display panel 200 is disposed on a side of the optical film group 20 away from the light-emitting substrate 10.

The display module 1000 has the same beneficial effects as the aforementioned light-emitting substrate 10, which will not be repeated here.

Some embodiments of the present disclosure provide a display apparatus 10000. As shown in FIG. 13, the display apparatus 10000 includes the display module provided in the above embodiments.

The display apparatus 10000 may be any apparatus that displays images whether in motion (e.g., a video) or stationary (e.g., static images), and whether textual or graphical. More specifically, it is expected that the embodiments may be implemented in or associated with a plurality of electronic devices, and the plurality of electronic devices include (but are not limit to), for example, a mobile phone, a wireless device, a personal data assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a rear view camera display in a vehicle), an electronic photo, an electronic billboard or indicator, a projector, a building structure, a packaging and an aesthetic structure (e.g., a display for an image of a piece of jewelry).

For example, the display apparatus 10000 may further include a frame and other electronic components. The display panel 200 may, for example, be disposed in the frame.

The display apparatus 10000 has the same beneficial effects as the aforementioned light-emitting substrate 10, which will not be repeated here.

The above are merely specific embodiments of the present disclosure, but the protection scope of the present disclosure is not limited thereto, and variations or substitutions that any person skilled in the art may conceive of within the technical scope of the present disclosure, should fall within the protection scope of the present disclosure. Therefore, the protection scope of the present disclosure should be determined by the protection scope of the claims.

1. A light-emitting substrate, comprising:
a substrate including a first surface;
a plurality of signal lines disposed on the first surface;
one or more support structures disposed on the first surface; and
a device layer disposed on a side of the plurality of signal lines away from the first surface, wherein
a ratio of an overlapping area of an orthographic projection of any signal line of the plurality of signal lines on the substrate and an orthographic projection of at least one support structure of the one or more support structures on the substrate to an area of the orthographic projection of the at least one support structure on the substrate is greater than or equal to zero and less than or equal to 0.1.

2. The light-emitting substrate according to claim 1, wherein the plurality of signal lines include at least one first signal line, a first signal line of the at least one first signal line includes at least two straight sub-portions and at least one detour sub-portion, and all straight sub-portions and all detour sub-portions of the first signal line are alternately arranged;
an orthographic projection of a support structure of the one or more support structures on the substrate is divided into a first sub-region and a second sub-region by a reference line extending in a first direction, and a maximum value of a dimension of the first sub-region in a second direction is equal to a maximum value of a dimension of the second sub-region in the second direction; the first direction is perpendicular to the second direction; and
a straight sub-portion of the first signal line extends in the first direction and includes an inner border and an outer border both extending in the first direction, and an orthographic projection of an extension line of the inner border of the straight sub-portion of the first signal line on the substrate passes through the orthographic projection of the support structure adjacent to the straight sub-portion on the substrate.

3. The light-emitting substrate according to claim 2, wherein a detour sub-portion of the first signal line includes an inner border proximate to the reference line and an outer border away from the reference line, the inner border of the detour sub-portion of the first signal line is connected to the inner border of the straight sub-portion of the first signal line, and the outer border of the detour sub-portion of the first signal line is connected to the outer border of the straight sub-portion of the first signal line;
in the second direction, a maximum value of a distance between the reference line and the inner border of the detour sub-portion of the first signal line is greater than a distance between the reference line and the inner border of the straight sub-portion of the first signal line; and
the outer border of the detour sub-portion of the first signal line is located on a side of the support structure in the second direction, an orthographic projection of the outer border of the detour sub-portion of the first signal line on the substrate is non-overlapping with the orthographic projection of the support structure on the substrate, and a distance between the reference line and the outer border of the detour sub-portion of the first signal line is greater than a distance between the reference line and the outer border of the straight sub-portion of the first signal line.

4. The light-emitting substrate according to claim 3, wherein the detour sub-portion of the first signal line is located on a side of the support structure, and both ends of the detour sub-portion of the first signal line are each directly connected to a straight sub-portion, wherein
a symmetry axis, extending in the first direction, of the straight sub-portion of the first signal line is located on a side of the reference line, and the detour sub-portion of the first signal line and the symmetry axis are located on a same side of the reference line; or
the symmetry axis, extending in the first direction, of the straight sub-portion of the first signal line coincides with the reference line, and the detour sub-portion of the first signal line is located on either side of the reference line.

5. The light-emitting substrate according to claim 4, wherein a dimension of the detour sub-portion of the first signal line in a direction perpendicular to an extension direction of the detour sub-portion of the first signal line is greater than or equal to a dimension of the straight sub-portion of the first signal line in a direction perpendicular to an extension direction of the straight sub-portion of the first signal line.

6. The light-emitting substrate according to claim 3, wherein the plurality of signal lines include at least one second signal line, and a second signal line of the at least one second signal line is at least adjacent to one first signal line;
the second signal line includes at least two straight sub-portions and at least one detour sub-portion, and all straight sub-portions and all detour sub-portions of the second signal line are alternately arranged;
wherein a straight sub-portion of the second signal line extends in the first direction, and a detour sub-portion of the second signal line is further away from the support structure than the detour sub-portion of the first signal line.

7. The light-emitting substrate according to claim 6, wherein the detour sub-portion of the second signal line is arranged along a border of the detour sub-portion of the first signal line adjacent to the second signal line;
the straight sub-portion of the second signal line includes an inner border and an outer border both extending in the first direction;
the detour sub-portion of the second signal line includes an inner border proximate to the first signal line adjacent to the second signal line and an outer border away from the first signal line adjacent to the second signal line; the inner border of the detour sub-portion of the second signal line is connected to the inner border of the straight sub-portion of the second signal line, and the outer border of the detour sub-portion of the second signal line is connected to the outer border of the straight sub-portion of the second signal line; and
a shape of the inner border of the detour sub-portion of the second signal line is same as a shape of the outer border of the detour sub-portion of the first signal line adjacent to the second signal line.

8. The light-emitting substrate according to claim 7, wherein a dimension of the detour sub-portion of the second signal line in a direction perpendicular to an extension direction of the detour sub-portion of the second signal line is greater than or equal to a dimension of the straight sub-portion of the second signal line in a direction perpendicular to an extension direction of the straight sub-portion of the second signal line.

9. The light-emitting substrate according to claim 1, wherein the plurality of signal lines include at least one first signal line, a first signal line of the at least one first signal line includes at least two straight sub-portions and at least one detour sub-portion, and all straight sub-portions and all detour sub-portions of the first signal line are alternately arranged;
wherein a straight sub-portion of the first signal line extends in a first direction and includes an inner border and an outer border both extending in the first direction, and an orthographic projection of an extension line of the inner border of the straight sub-portion of the first signal line on the substrate passes through an orthographic projection of a support structure adjacent to the straight sub-portion on the substrate; the orthographic projection of the support structure on the substrate is divided into a first sub-region and a second sub-region by a reference line extending in the first direction, and a maximum value of a dimension of the first sub-region in a second direction is equal to a maximum value of a dimension of the second sub-region in the second direction; the first direction is perpendicular to the second direction;
a detour sub-portion of the first signal line includes an inner border proximate to the reference line and an outer border away from the reference line, the inner border of the detour sub-portion of the first signal line is connected to the inner border of the straight sub-portion of the first signal line, and the outer border of the detour sub-portion of the first signal line is connected to the outer border of the straight sub-portion of the first signal line; and
in the second direction, a maximum value of a distance between the reference line and the inner border of the detour sub-portion of the first signal line is greater than a distance between the reference line and the inner border of the straight sub-portion of the first signal line; the outer border of the detour sub-portion of the first signal line is located on a side of the support structure in the second direction, an orthographic projection of the outer border of the detour sub-portion of the first signal line on the substrate is non-overlapping with the orthographic projection of the support structure on the substrate, and the outer border of the detour sub-portion of the first signal line is collinear with the outer border of the straight sub-portion of the first signal line.

10. The light-emitting substrate according to claim 9, wherein a dimension of the detour sub-portion of the first signal line in a direction perpendicular to an extension direction of the detour sub-portion of the first signal line is less than a dimension of the straight sub-portion of the first signal line in a direction perpendicular to an extension direction of the straight sub-portion of the first signal line; and
the dimension of the detour sub-portion of the first signal line in the direction perpendicular to the extension direction of the detour sub-portion of the first signal line is greater than or equal to 100 km.

11. The light-emitting substrate according to claim 2, wherein
the detour sub-portion of the first signal line is arranged along a border of the orthographic projection of the support structure on the substrate; and
a shape of the inner border of the detour sub-portion of the first signal line matches a shape of the border of the orthographic projection of the support structure on the substrate.

12. The light-emitting substrate according to claim 11, wherein the plurality of signal lines include at least two first signal lines, and the support structure is surrounded by detour sub-portions of two first signal lines of the at least two first signal lines adjacent to the support structure.

13. The light-emitting substrate according to claim 12, wherein the light-emitting substrate further comprises an insulating layer disposed on a side of the plurality of signal lines away from the first surface, the insulating layer covering the plurality of signal lines; wherein
the insulating layer is located between the plurality of signal lines and the support structure, and an orthographic projection of the insulating layer on the substrate overlaps with the orthographic projection of the support structure on the substrate; and
in a direction perpendicular to the first surface, a distance between the first surface and a surface of a portion of the insulating layer located between the support structure and the substrate is less than a distance between the first surface and a surface of a portion of the insulating layer covering the plurality of signal lines.

14. The light-emitting substrate according to claim 13, wherein a region covered by the orthographic projection of the support structure on the substrate is a support region, wherein
an adhesive is provided in the support region, and an end of the support structure is fixed to the support region by the adhesive; or
a blind hole is provided in the support region, and an end of the support structure is disposed in the blind hole; or
a through hole penetrating the substrate in the direction perpendicular to the first surface is provided in the support region, and an end of the support structure is disposed in the through hole.

15. The light-emitting substrate according to claim 1, wherein a colour of the support structure includes white.

16. The light-emitting substrate according to claim 1, wherein the orthographic projection of the support structure on the substrate is in a shape of a circle, an ellipse or a polygon.

17. The light-emitting substrate according to claim 1, wherein the device layer includes a plurality of light-emitting devices and a plurality of driving circuits, and the plurality of driving circuits are configured to drive the plurality of light-emitting devices to emit light.

18. A backlight module, comprising:
the light-emitting substrate according to claim 1; and
an optical film group disposed on a side of the device layer away from the substrate, wherein the device layer and the optical film group have a set distance therebetween;
an end of a support structure of the one or more support structures away from the substrate abuts against the optical film group.

19. A display module, comprising:
the backlight module according to claim 18; and
a display panel disposed on a side of the optical film group away from the light-emitting substrate.

20. A display apparatus, comprising: the display module according to claim 19.
